(19) United States
(12) Patent Application Publication
(10) Pub. No.: US 2025/0280532 A1
(43) Pub. Date: Sep. 4, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: KOHJI KANAMORI, Suwon-si (KR); SEO-GOO KANG, Suwon-si (KR); JUNGHOON JUN, Suwon-si (KR); JEEHOON HAN, Suwon-si (KR)

(21) Appl. No.: 18/941,004

(22) Filed: Nov. 8, 2024

(30) Foreign Application Priority Data
Feb. 29, 2024 (KR) 10-2024-0029646

(51) Int. Cl. H10B 12/00; H01L 23/00; H01L 25/18; H10B 80/00

(52) U.S. Cl. CPC H10B 12/50; H01L 24/08; H01L 25/18; H10B 12/482; H10B 12/485; H10B 12/488; H10B 80/00; H01L 2224/08147; H01L 2225/06513; H01L 2924/1436

(57) ABSTRACT

A semiconductor memory device includes a first cell array structure including a plurality of first cell strings, a plurality of first bonding pads, a first bit line, and a first common source line, and a plurality of first word lines; and a second cell array structure including a plurality of second cell strings, a plurality of second bonding pads, a second bit line, a second common source line, and a plurality of second word lines, where the plurality of first bonding pads are bonded to the plurality of second bonding pads, where the plurality of first word lines are electrically connected to the plurality of second word lines, where the first bit line is electrically separated from the second bit line, and where the first common source line is electrically separated from the second common source line.

### CROSS-REFERENCE TO RELATED APPLICATION

This U.S. nonprovisional application claims priority under 35 U.S.C. § 119 to Korean Patent Application No. 10-2024-0029646 filed on Feb. 29, 2024 in the Korean Intellectual Property Office, the disclosure of which is hereby incorporated by reference in its entirety.

### TECHNICAL FIELD

The present disclosure relate to a semiconductor memory device and an electronic system including the same.

### BACKGROUND

It is desirable to have a semiconductor device capable of storing a large amount of data in an electronic system that stores data. Therefore, studies have been conducted to increase data storage capacity of the semiconductor device. For example, as an approach to increase data storage capacity of the semiconductor device, a semiconductor device has been suggested to include three-dimensionally arranged memory cells instead of two-dimensionally arranged memory cells.

### SUMMARY

Some embodiments of the present disclosure provide a semiconductor memory device with improved reliability and increased integration.

Some embodiments of the present disclosure provide an electronic system including a semiconductor memory device.

The object of the present disclosure is not limited to the above description, and other objects which have not been mentioned above will be clearly understood to those skilled in the art from the following description.

According to some embodiments of the present disclosure, a semiconductor memory device may include: a first cell array structure that includes a plurality of first cell strings and a plurality of first bonding pads respectively electrically connected to the plurality of first cell strings, where the first cell strings are electrically connected to a first bit line and a first common source line, and where each of the plurality of first cell strings includes a plurality of first memory cells that are respectively electrically connected to a plurality of first word lines; and a second cell array structure that includes a plurality of second cell strings and a plurality of second bonding pads respectively electrically connected to the plurality of second cell strings, where the second cell strings are electrically connected to a second bit line and a second common source line, and where each of the plurality of second cell strings includes a plurality of second memory cells that are respectively electrically connected to a plurality of second word lines, where the plurality of first bonding pads are respectively directly bonded to the plurality of second bonding pads, where the plurality of first word lines are respectively electrically connected to the plurality of second word lines, where the first bit line is spaced apart from the second bit line in a first direction that is perpendicular to an upper surface of the first cell array structure, and where the first common source line is spaced apart from the second common source line in the first direction.

According to some embodiments of the present disclosure, a semiconductor memory device may include: a peripheral circuit structure that includes a plurality of peripheral circuits on a substrate and a plurality of first bonding pads electrically connected to the peripheral circuits; a first cell array structure that includes a plurality of second bonding pads that are on a first surface of the first cell array structure and are respectively electrically connected to the first bonding pads, where the first cell array structure includes a plurality of third bonding pads that are on a second surface of the first cell array structure that is opposite to the first surface of the first cell array structure, where the first cell array structure includes a first stack and a plurality of first vertical structures that extend into the first stack, the first stack including a first bit line, a first common source line, and a plurality of first word lines between the first bit line and the first common source line; a second cell array structure that includes a plurality of fourth bonding pads respectively electrically connected to the third bonding pads, where the second cell array structure includes a second stack and a plurality of second vertical structures that extend into the second stack, the second stack including a second bit line, a second common source line, and a plurality of second word lines between the second bit line and the second common source line; a plurality of first connection lines that electrically connect respective ones of the first word lines to respective ones of the second word lines; a first bit-line connection line and a second bit-line connection line that are respectively electrically connected to the first bit line and the second bit line; and a first source connection line and a second source connection line that are respectively electrically connected to the first common source line and the second common source line.

According to some embodiments of the present disclosure, an electronic system may include: a semiconductor memory device that includes a peripheral circuit structure and a memory block on the peripheral circuit structure; and a controller electrically connected to and configured to control the semiconductor memory device, where the memory block includes: a first cell array structure that includes a plurality of first cell strings and a plurality of first bonding pads respectively electrically connected to the plurality of first cell strings, where the plurality of first cell strings are electrically connected between a first bit line and a first common source line, and where each of the plurality of first cell strings includes a plurality of first memory cells that are respectively electrically connected to a plurality of first word lines; and a second cell array structure that includes a plurality of second cell strings and a plurality of second bonding pads respectively electrically connected to the plurality of second cell strings, where the plurality of second cell strings are electrically connected between a second bit line and a second common source line, and where each of the plurality of second cell strings includes a plurality of second memory cells that are respectively electrically connected to a plurality of second word lines, where the plurality of first bonding pads are respectively directly bonded to the second bonding pads, where the plurality of first word lines are respectively electrically connected to the plurality of second word lines, where the first bit line is spaced apart from the second bit line in a first direction that is perpendicular to an upper surface of the first cell array structure, and where the first common source line is spaced apart from the second common source line in the first direction.

Details of other embodiments are included in the description and drawings.

### BRIEF DESCRIPTION OF DRAWINGS

FIG. 1 illustrates a block diagram showing a semiconductor memory device according to some embodiments of the present disclosure.

FIG. 2 illustrates a simplified circuit diagram showing a semiconductor memory device according to some embodiments of the present disclosure.

FIG. 3 illustrates a circuit diagram showing a memory cell array of a semiconductor memory device according to some embodiments of the present disclosure.

FIG. 4 illustrates a cross-sectional view showing a semiconductor memory device according to some embodiments of the present disclosure.

FIG. 5 illustrates a cross-sectional view partially showing a semiconductor memory device according to some embodiments of the present disclosure.

FIG. 6 illustrates an enlarged view showing sections P1 and P2 of FIG. 5.

FIG. 7 illustrates a cross-sectional view partially showing a semiconductor memory device according to some embodiments of the present disclosure.

FIG. 8 illustrates an enlarged view showing sections P1 and P2 of FIG. 7.

FIG. 9 illustrates a cross-sectional view showing a semiconductor memory device according to some embodiments of the present disclosure.

FIG. 10 illustrates a cross-sectional view showing a semiconductor memory device according to some embodiments of the present disclosure.

FIG. 11 illustrates a simplified circuit diagram showing a semiconductor memory device according to some embodiments of the present disclosure.

FIG. 12A illustrates a flow chart showing an erase operation of a semiconductor memory device according to some embodiments of the present disclosure.

FIG. 12B illustrates a circuit diagram showing a bias condition in an erase operation of a semiconductor memory device according to some embodiments of the present disclosure.

FIG. 13A illustrates a flow chart showing an erase operation of a semiconductor memory device according to some embodiments of the present disclosure.

FIGS. 13B and 13C illustrate circuit diagrams showing a bias condition in an erase operation of a semiconductor memory device according to some embodiments of the present disclosure.

FIGS. 14, 15, 16, 17, 18, 19, and 20 illustrate diagrams showing a method of fabricating a semiconductor memory device according to some embodiments of the present disclosure.

FIG. 21 illustrates a simplified diagram showing an electronic system including a semiconductor memory device according to some embodiments of the present disclosure.

FIG. 22 illustrates a simplified diagram showing an electronic system including a semiconductor memory device according to some embodiments of the present disclosure.

FIGS. 23 and 24 illustrate simplified cross-sectional views showing a semiconductor package according to some embodiments of the present disclosure.

### DETAILED DESCRIPTION OF EMBODIMENTS

To clarify the present disclosure, parts that are not connected with the description will be omitted, and the same elements or equivalents are referred to by the same reference numerals throughout the specification. In the drawings, the thickness of layers, films, panels, regions, etc., are exaggerated for clarity. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

With reference to drawings, the following will describe in detail a semiconductor memory device and an electronic system including the same according to some embodiments of the present disclosure.

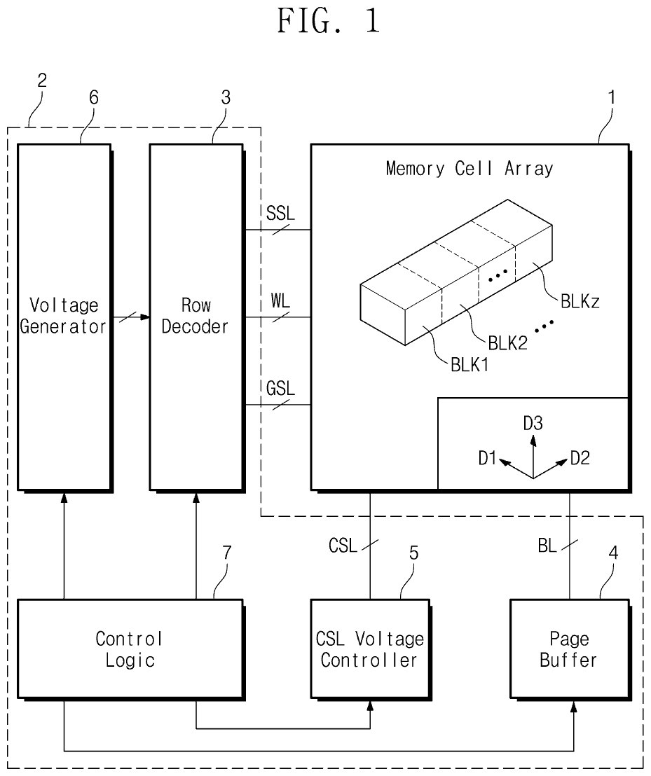

FIG. 1 illustrates a simplified block diagram showing a semiconductor device according to some embodiments of the present disclosure.

Referring to FIG. 1, a semiconductor memory device may include a memory cell array 1 and a peripheral circuit 2 that controls the memory cell array 1. The peripheral circuit 2 may include a row decoder 3, a page buffer 4, a common source line (CSL) voltage controller 5, a voltage generator 6, and a control logic 7.

The memory cell array 1 may include a plurality of memory blocks BLK1 to BLKz. Each of the memory blocks BLK1 to BLKz may include three-dimensionally arranged memory cells. For example, each of the memory blocks BLK1 to BLKz may include structures stacked along a third direction D3 on a plane elongated along first and second directions D1 and D2 that intersect each other. In response to a related block selection signal, the memory blocks BLK1 to BLKz may read data from or write data to a selected memory block. Memory cells of the memory cell array 1 may undergo an erase operation by a memory block unit.

The semiconductor memory device may be, for example, a vertical NAND Flash memory device. In the vertical NAND Flash memory device, the memory blocks BLK1 to BLKz may include a plurality of cell strings each being a NAND type.

Alternatively, the semiconductor memory device may be a variable resistance memory device. In the variable resistance memory device, the memory blocks BLK1 to BLKz may include memory cells correspondingly or respectively disposed at intersections between word lines and bit lines. In this description, each of the memory cells may include a resistive memory element. The resistive memory element may include perovskite compounds, transition metal oxide, phase-change materials, magnetic materials, ferromagnetic materials, or anti-ferromagnetic materials.

The row decoder 3 may decode externally input address to select at least one of a plurality of memory blocks BLK1 to BLKz, and may select word lines WL, a string selection line SSL, and a ground selection line GSL of the selected one of the memory blocks BLK1 to BLKz. The row decoder 3 may transmit a voltage for memory operation to the word line WL of the selected memory block.

The page buffer 4 may be connected through the bit lines BL to the memory cell array 1 and may read information stored in the memory cells.

The page buffer 4 may operate as a write driver during a program operation to provide the bit line BL with a voltage depending on data that will be stored in the memory cell array 1, and may operate as a sense amplifier during a read operation to detect data stored in the memory cell array 1. The page buffer 4 may operate based on a control signal provided from the control logic 7.

The CSL voltage controller 5 may be connected to the memory cell array 1 through a common source line CSL. Based on control of the control logic 7, the CSL voltage controller 5 may apply a common source voltage (e.g., power voltage or ground voltage) to the common source line CSL.

In accordance with control of the control logic 7, the voltage generator 6 may generate voltages (e.g., program voltage, read voltage, erase voltage, pass voltage, and verification voltage) for operating the memory cell array 1. The program voltage may be relatively higher (e.g., about 20 V to about 40 V) than the read voltage, the pass voltage, and the verification voltage.

Based on a command signal, an address signal, and a control signal, the control logic 7 may generate various control signals to program data to the memory cell array 1, to read data from the memory cell array 1, or to erase data stored in the memory cell array 1.

In some embodiments, the peripheral circuit 2 may include high-voltage transistors and low-voltage transistors. The row decoder 3 may include pass transistors connected to the word lines WL of memory cell strings. The pass transistors may include high-voltage transistors capable of withstanding high voltages such as program voltages applied to the word lines WL in a program operation. The page buffer 4 may also include high-voltage transistors capable of withstanding high voltages.

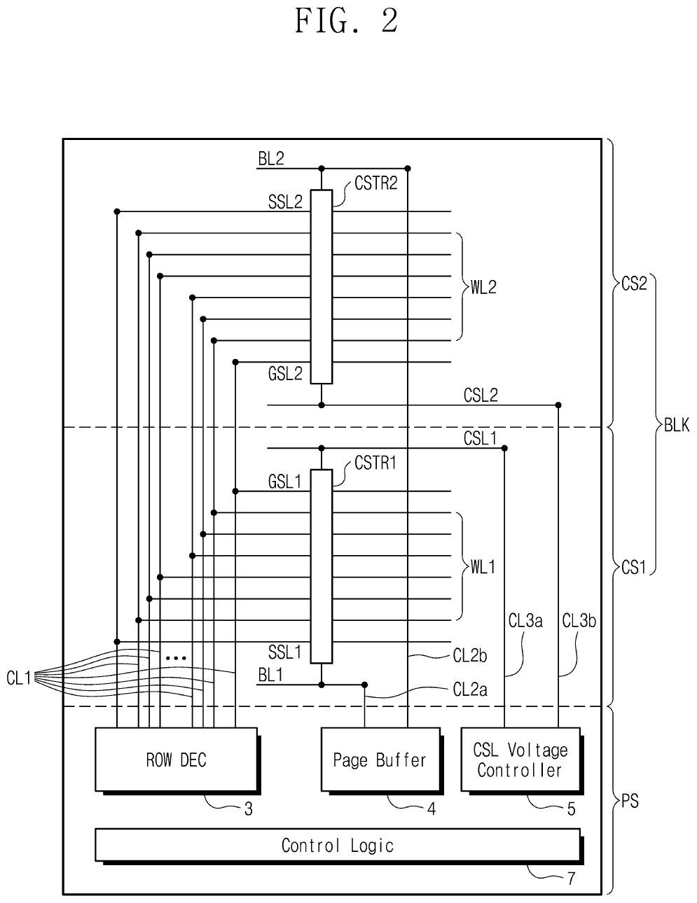

FIG. 2 illustrates a simplified circuit diagram showing a semiconductor memory device according to some embodiments of the present disclosure.

Referring to FIG. 2, a semiconductor memory device according to some embodiments of the present disclosure may include a peripheral circuit structure PS and a plurality of memory blocks BLK (each being a unit for erasing data) on the peripheral circuit structure PS.

When viewed in plan, each memory block BLK may overlap the peripheral circuit structure PS. In some embodiments, the peripheral circuit structure PS may include the row decoder 3, the page buffer 4, the CSL voltage controller 5, the voltage generator (see 6 of FIG. 1), and the control logic 7 that are discussed with reference to FIG. 1.

Each memory block BLK may include a first cell array structure CS1 on the peripheral circuit structure PS and a second cell array structure CS2 on the first cell array structure CS1.

In some embodiments, the first and second cell array structures CS1 and CS2 included in the memory block BLK may be manufactured separately on different wafers and then connected to each other by a bonding method. The bonding method may refer to a method in which a bonding metal formed on an uppermost metal layer of the first cell array structure CS1 is electrically connected to a bonding metal formed on an uppermost metal layer of the second cell array structure CS2. When the bonding metal is formed of copper (Cu), the bonding manner may be a copper-to-copper bonding.

The first and second cell array structures CS1 and CS2 may respectively include memory cell strings CSTR1 and CSTR2 each being a NAND type.

The first cell array structure CS1 may include a first bit line BL1, a first string selection line SSL1, first word lines WL1, a first ground selection line GSL1, a first common source line CSL1, and a first memory cell string CSTR1. In the first cell array structure CS1, the first memory cell string CSTR1 may be provided in plural.

A second cell array structure CS2 may include a second bit line BL2, a second string selection line SSL2, second word lines WL2, a second ground selection line GSL2, a second common source line CSL2, and a second memory cell string CSTR2. In the second cell array structure CS2, the second memory cell string CSTR2 may be provided in plural.

The first word lines WL1 of the first cell array structure CS1 and the second word lines WL2 of the second cell array structure CS2 may be connected to the row decoder 3 through first connection lines CL1.

The first and second ground selection lines GSL1 and GSL2 of the first and second cell array structures CS1 and CS2 may be connected to the row decoder 3 through the first connection lines CL1. The first and second string selection lines SSL1 and SSL2 of the first and second cell array structures CS1 and CS2 may be connected to the row decoder 3 through first connection lines CL1. The first and second string selection lines SSL1 and SSL2 may be separated and controlled independently of each other. The first and second ground selection lines GSL1 and GSL2 may also be separated and controlled independently of each other. The first bit lines BL1 of the first cell array structure CS1 may be connected to the page buffer 4 through a first bit-line connection line CL2a, and the second bit lines BL2 of the second cell array structure CS2 may be connected to the page buffer 4 through a second bit-line connection line CL2b.

The first common source line CSL1 of the first cell array structure CS1 may be connected to the CSL voltage controller 5 through a first source connection line CL3a, and the second common source line CSL2 of the second cell array structure CS2 may be connected to the CSL voltage controller 5 through a second source connection line CL3b.

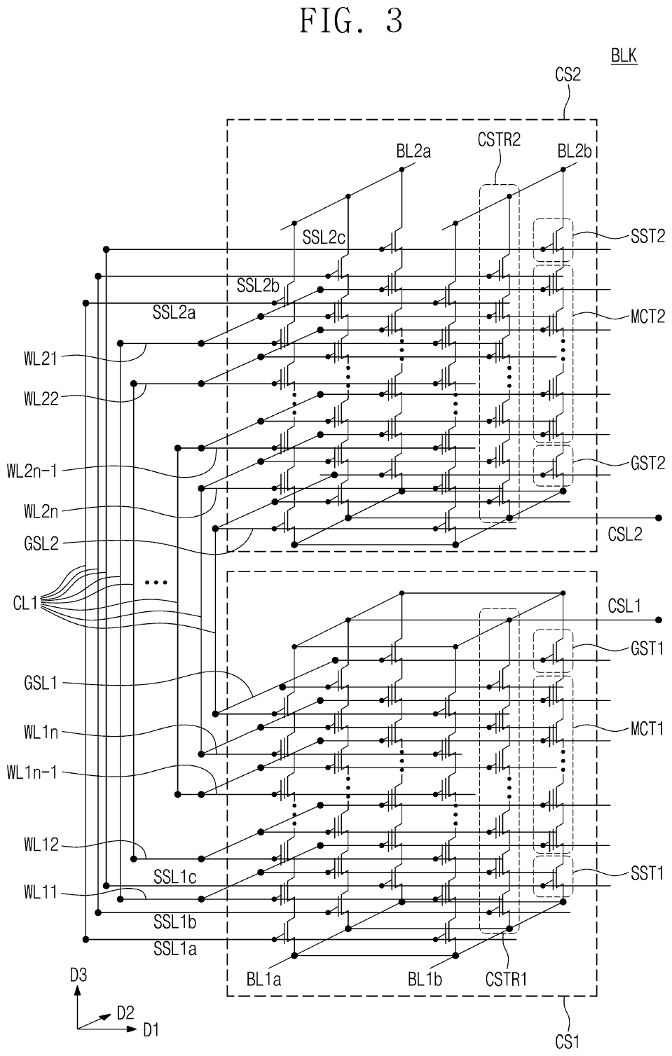

FIG. 3 illustrates a circuit diagram showing a memory cell array of a semiconductor memory device according to some embodiments of the present disclosure.

Referring to FIG. 3, as discussed above, each memory block BLK may include a first cell array structure CS1 and a second cell array structure CS2.

The first cell array structure CS1 may include a first common source line CSL1, a plurality of first bit lines BL1a and BL1b, and a plurality of first memory cell strings CSTR1 disposed between the first common source line CSL1 and the first bit lines BL1a and BL1b.

The first memory cell strings CSTR1 may extend along a third direction D3 on a plane elongated along first and second directions D1 and D2. The first memory cell strings CSTR1 may be two-dimensionally arranged along the first and second directions D1 and D2 that intersect each other.

The first bit lines BL1a to BL1b may be spaced apart from each other in the first direction D1 and may extend in the second direction D2.

The first memory cell strings CSTR1 may be connected in parallel to each of the first bit lines BL1a and BL1b. A plurality of first memory cell strings CSTR1 may be connected in common to the first common source line CSL1. For example, a plurality of first memory cell strings CSTR1 may be disposed between a plurality of first bit lines BL1a and BL1b and a single first common source line CSL1. A plurality of first common source lines CSL1 may be two-dimensionally arranged. The first common source lines CSL1 may be supplied with the same voltage or may be electrically controlled individually from each other.

According to some embodiments, each of the first memory cell strings CSTR1 may include a first string selection transistor SST1, first memory cell transistors MCT1 that are connected to each other in series, and a first ground selection transistor GST1. Moreover, each of the first memory cell transistors MCT1 may include a data storage element.

For example, in each of the first memory cell strings CSTR1, the first string selection transistor SST1 may be coupled to the first bit line BL1a or BL1b, and the first ground selection transistor GST1 may be coupled to the first common source line CSL1. The first memory cell transistors MCT1 may be connected in series between the first string selection transistor SST1 and the first ground selection transistor GST1. Although not shown, each of the first memory cell strings CSTR1 may include a lower erase control transistor connected in series between the first ground selection transistor GST1 and the first common source line CSL1, and may also include an upper erase control transistor connected in series between the first bit line BL1a or BL1b and the first string selection transistor SST1. One or both of the lower and upper erase control transistors may be employed to perform an erase operation in which a gate induced drain leakage (GIDL) phenomenon is used to erase data stored in the first memory cell transistors MCT1.

According to some embodiments, the first string selection transistor SST1 may be controlled by first string selection lines SSL1a, SSL1b, and SSL1c, and the first memory cell transistors MCT1 may be controlled by a plurality of first word lines WL11 to WL1n. In addition, the first ground selection transistor GST1 may be controlled by the first ground selection line GSL1. The first common source line CSL1 may be connected in common to sources of the first ground selection transistors GST1.

The first memory cell transistors MCT1 may have their gate electrodes disposed at substantially the same distance in the third direction D3 from the first common source lines CSL1, and the gate electrodes of the first memory cell transistors MCT1 may be connected in common to one of the first word lines WL11 to WL1n and have the same potential state.

The first ground selection lines GSL1 and the first string selection lines SSL1a, SSL1b, and SSL1c located at substantially the same level in the third direction D3 from the first common source lines CSL1 may be electrically separated or spaced apart from each other.

The second cell array structure CS2 may include a second common source line CSL2, a plurality of second bit lines BL2a and BL2b, and a plurality of second memory cell strings CSTR2 disposed between the second common source line CSL2 and the second bit lines BL2a and BL2b.

The second memory cell strings CSTR2 may extend along the third direction D3 on a plane elongated along the first and second directions D1 and D2. The second memory cell strings CSTR2 may be two-dimensionally arranged along the first and second directions D1 and D2 that intersect each other.

The second bit lines BL2a and BL2b may be spaced apart from each other in the first direction D1 and may extend in the second direction D2.

The second memory cell strings CSTR2 may be connected in parallel to each of the second bit lines BL2a and BL2b. A plurality of second memory cell strings CSTR2 may be connected in common to the second common source line CSL2. For example, a plurality of second memory cell strings CSTR2 may be disposed between a plurality of second bit lines BL2a and BL2b and a single second common source line CSL2. A plurality of second common source lines CSL2 may be two-dimensionally arranged. The second common source lines CSL2 may be supplied with the same voltage or may be electrically controlled individually from each other.

According to some embodiments, each of the second memory cell strings CSTR2 may include a second string selection transistor SST2, second memory cell transistors MCT2 that are connected to each other in series, and a second ground selection transistor GST2. Moreover, each of the second memory cell transistors MCT2 may include a data storage element.

For example, in each of the second memory cell strings CSTR2, the second string selection transistor SST2 may be coupled to the second bit line BL2a or BL2b, and the second ground selection transistor GST2 may be coupled to the second common source line CSL2. The second memory cell transistors MCT2 may be connected in series between the second string selection transistor SST2 and the second ground selection transistor GST2. Although not shown, each of the second memory cell strings CSTR2 may include a lower erase control transistor connected in series between the second ground selection transistor GST2 and the second common source line CSL2, and may also include an upper erase control transistor connected in series between the second bit line BL2a or BL2b and the second string selection transistor SST2. One or both of the lower and upper erase control transistors may be employed to perform an erase operation in which a gate induced drain leakage (GIDL) phenomenon is used to erase data stored in the second memory cell transistors MCT2.

According to some embodiments, the second string selection transistor SST2 may be controlled by second string selection lines SSL2a, SSL2b, and SSL2c, and the second memory cell transistors MCT2 may be controlled by a plurality of second word lines WL21 to WL2n. In addition, the second ground selection transistor GST2 may be controlled by a corresponding second ground selection line GSL2. The second common source line CSL2 may be connected in common to sources of the second ground selection transistors GST2.

The second memory cell transistors MCT2 may have their gate electrodes disposed at substantially the same distance in the third direction D3 from the second common source lines CSL2, and the gate electrodes of the second memory cell transistors MCT2 may be connected in common to one of the second word lines WL21 to WL2n and have the same potential state.

The second ground selection lines GSL2 and the second string selection lines SSL2a, SSL2b, and SSL2c located at substantially the same level in the third direction D3 from the second common source lines CSL2 may be electrically separated or spaced apart from each other.

According to some embodiments, the first word lines WL11, WL12 to WL1n-1, and WL1n of the first cell array structure CS1 and the second word lines WL21, WL21 to WL2n-1, and WL2n of the second cell array structure CS2 may be connected in common to the first connection lines CL1.

The first string selection lines SSL1a, SSL1b, and SSL1c of the first cell array structure CS1 may be correspondingly or respectively connected through the first connection lines CL1 to the second string selection lines SSL2a, SSL2b, and SSL2b of the second cell array structure CS2.

The first ground selection lines GSL1 of the first cell array structure CS1 may be connected through the first connection lines CL1 to the second ground selection lines GSL2 of the second cell array structure CS2.

The first and second word lines WL1 and WL2 of the first and second cell array structures CS1 and CS2 may be connected in common, while the first string selection lines SSL1a, SSL1b, SSL1c and the second string selection lines SSL2a, SSL2b, and SSL2c may be separated or spaced apart from each other and controlled independently of each other, and the first and second ground selection transistors GSL1 and GSL2 may also be separated or spaced apart from each other and controlled independently of each other.

The first bit lines BL1a and BL1b of the first cell array structure CS1 may be controlled independently of the second bit lines BL2a and BL2b of the second cell array structure CS2. Therefore, write and/or read operations may be separately and independently performed for the first cell array structure CS1 and the second cell array structure CS2.

In addition, the first common source line CSL1 of the first cell array structure CS1 may be controlled independently of the second common source line CSL2 of the second cell array structure CS2. Therefore, an erase operation may be separately and independently performed for the first cell array structure CS1 and the second cell array structure CS2.

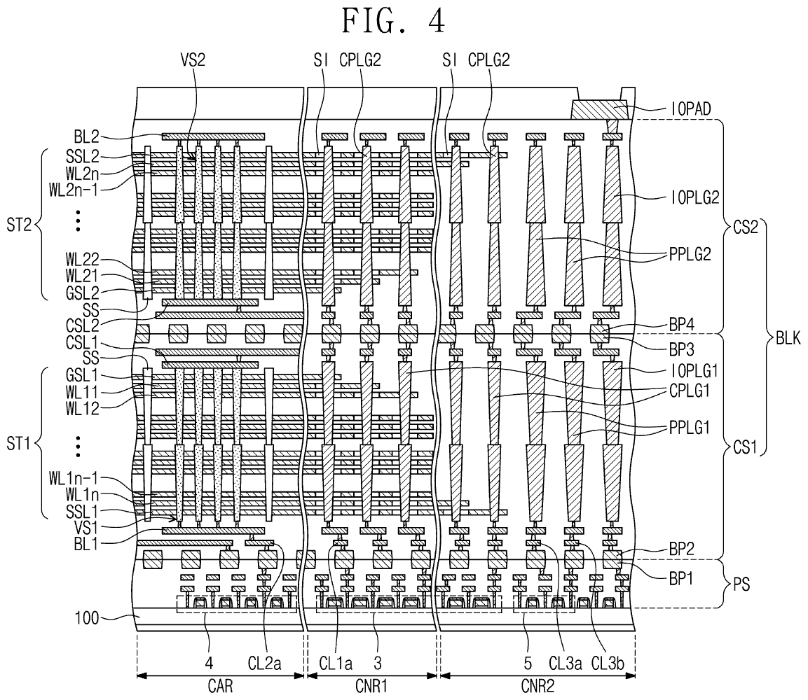

FIG. 4 illustrates a cross-sectional view showing a semiconductor memory device according to some embodiments of the present disclosure.

Referring to FIG. 4, a semiconductor memory device may include a substrate 100, a peripheral circuit structure PS on the substrate 100, and a memory block BLK on the peripheral circuit structure PS. The memory block BLK may include a first cell array structure CS1 on the peripheral circuit structure PS and a second cell array structure CS2 on the first cell array structure CS1.

The peripheral circuit structure PS may include peripheral circuits that are integrated on a front surface of the substrate 100 and control a memory cell array, and may also include first bonding pads BP1 connected to the peripheral circuits.

The peripheral circuits may include the row decoder 3, the page buffer 4, the CSL voltage controller 5, and the control logic 7 that are discussed with reference to FIGS. 1 and 2.

The substrate 100 may be, for example, a silicon substrate, a silicon-germanium substrate, a germanium substrate, or a monocrystalline epitaxial layer grown on a monocrystalline silicon substrate. The substrate 100 may include a cell array region CAR, a first connection region CNR1, and a second connection region CNR2.

The substrate 100 on the cell array region CAR may be provided thereon with the page buffer 4 connected to first and second bit lines BL1 and BL2. The substrate 100 on the first connection region CNR1 may be provided thereon with the row decoder 3 connected to first and second word lines WL11 to WL1n and WL21 to WL2n. The substrate 100 on the second connection region CNR2 may be provided thereon with the CSL voltage controller 5 and the control logic 7 that are connected to first and second common source lines CSL1 and CSL2.

First bonding pads BP1 may be disposed in an uppermost dielectric layer of the peripheral circuit structure PS. The first bonding pads BP1 may be connected to the peripheral circuits through peripheral circuit lines (e.g., conductive lines and conductive plugs). The first bonding pads BP1 may be formed of, for example, copper.

The first cell array structure CS1 may be provided on the peripheral circuit structure PS. The first cell array structure CS1 may include first memory cell strings CSTR1 including first memory cells MC1 that are three-dimensionally arranged as discussed with reference to FIG. 3.

The first cell array structure CS1 may include a first common source line CSL1, a first stack ST1, first vertical structures VS1, first bit lines BL1, first cell contact plugs CPLG1, first peripheral contact plugs PPLG1, and first input/output contact plugs IOPLG1. In addition, the first cell array structure CS1 may further include second bonding pads BP2 bonded to the first bonding pads BP1 and third bonding pads BP3 opposite to the second bonding pads BP2.

The first stack ST1 may include first conductive patterns SSL1, WL11 to WL1n, and GSL1 and first interlayer dielectric layers that are alternately stacked along a direction perpendicular to a top surface of the substrate 100.

The first conductive patterns SSL1, WL11 to WL1n, and GSL1 may include, for example, at least one selected from doped semiconductor (e.g., doped silicon), metal (e.g., tungsten, molybdenum, nickel, copper, or aluminum), conductive metal nitride (e.g., titanium nitride or tantalum nitride), and/or transition metal (e.g., titanium or tantalum). The first interlayer dielectric layers may include one or more of silicon oxide, silicon nitride, silicon oxynitride, and low-k dielectrics. For example, the first interlayer dielectric layers may include high density plasma (HDP) oxide or tetraethylorthosilicate (TEOS).

The first stack ST1 may be disposed between separation structures SS that extend in parallel along one direction. The separation structures SS may include a dielectric material, such as silicon oxide. The first stack ST1 of the first cell array structure CS1 may be provided in plural, and the plurality of first stacks ST1 may extend in parallel along one direction.

The first conductive patterns SSL1, WL11 to WL1n, and GSL1 of the first stack ST1 may be stacked to have a stepwise structure on the first connection region CNR1. For example, the first conductive patterns SSL1, WL11 to WL1n, and GSL1 may have their lengths that reduce with increasing distance from the peripheral circuit structure PS.

According to some embodiments, the semiconductor memory device may be a vertical NAND Flash memory device, and in this case, the first conductive patterns SSL1, WL11 to WL1n, and GSL1 of the first stack ST1 may be used as or correspond to the first string selection lines SSL1a, SSL1b, and SSL1c, the first word lines WL11 to WL1n, and the ground selection lines GSL1 discussed with reference to FIG. 3.

The first conductive patterns SSL1, WL11 to WL1n, and GSL1 may each include a pad part on the first connection region CNR1. The pad parts of the first conductive patterns SSL1, WL11 to WL1n, and GSL1 may be located at positions that are horizontally and vertically different from each other. The first cell contact plugs CPLG1 may be correspondingly or respectively coupled to the pad parts of the first conductive patterns SSL1, WL11 to WL1n, and GSL1.

A plurality of first vertical structures VS1 may vertically overlap the first stack ST1 on the cell array region CAR. When viewed in plan, the first vertical structures VS1 may be arranged in a straight or zigzag fashion along one direction. Each of the first vertical structures VS1 may include a vertical channel formed of a semiconductor material. Each of the first vertical structures VS1 may include a lower part that penetrates or extends into a lower portion of the first stack ST1 and an upper part that penetrates or extends into an upper portion of the first stack ST1. Each of the lower and upper portions of the first stack ST1 may have a width that gradually increases with increasing distance from the substrate 100.

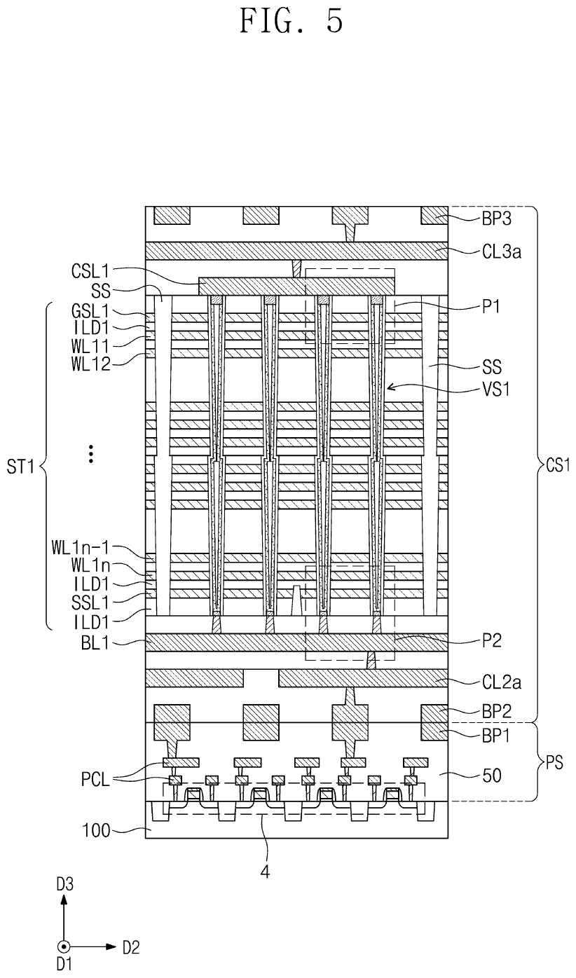

A detailed structure of the first vertical structures VS1 will be described in detail below with reference to FIGS. 5 to 8.

According to some embodiments, the first bit lines BL1 may be disposed between the first stack ST1 and the peripheral circuit structure PS in a direction perpendicular to the top surface of the substrate 100 (referred to hereinafter as a vertical direction). Each of the first bit lines BL1 may be electrically connected to the first vertical structures VS1 that are arranged along an extending direction thereof. The first bit lines BL1 may be electrically connected through first bit-line connection lines CL2a to the second bonding pads BP2. The first bit lines BL1 may include, for example, at least one selected from a doped semiconductor (e.g., doped silicon), metal (e.g., tungsten, molybdenum, nickel, copper, or aluminum), conductive metal nitride (e.g., titanium nitride or tantalum nitride), and/or transition metal (e.g., titanium or tantalum).

The first common source line CSL1 may be disposed on an uppermost first interlayer dielectric layer of the first stack ST1. The first common source line CSL1 may be in direct contact with top surfaces of the first vertical structures VS1. The first common source line CSL1 may be electrically connected through first source connection lines CL3a to the second bonding pads BP2. The first common source line CSL1 may include, for example, at least one selected from a doped semiconductor (e.g., doped silicon), metal (e.g., tungsten, molybdenum, nickel, copper, or aluminum), conductive metal nitride (e.g., titanium nitride or tantalum nitride), and/or transition metal (e.g., titanium or tantalum).

Upper and lower conductive lines may be disposed in upper and lower portions of the first stack ST1. The lower conductive lines disposed in the lower portion of the first stack ST1 may be electrically connected to the second bonding pads BP2, and the upper conductive lines disposed in the upper portion of the first stack ST1 may be electrically connected to the third bonding pads BP3.

On the first connection region CNR1, the first cell contact plugs CPLG1 may penetrate or extend into the first stack ST1 to be correspondingly or respectively coupled to the pad parts of the first conductive patterns SSL1, WL11 to WL1n, and GSL1. The first cell contact plugs CPLG1 may have substantially the same vertical length.

On the first connection region CNR1, the first cell contact plugs CPLG1 may correspondingly or respectively vertically penetrate or extend into the pad parts of the first conductive patterns SSL1, WL11 to WL1n, and GSL1. The first cell contact plugs CPLG1 may be electrically connected through the lower conductive lines to the second bonding pads BP2. The first cell contact plugs CPLG1 may be electrically connected through the lower conductive lines to the first conductive patterns SSL1, WL11 to WL1n, and GSL1 and the second bonding pads BP2. The first cell contact plugs CPLG1 may be electrically connected to the row decoder 3 of the peripheral circuit structure PS.

The first cell contact plugs CPLG1 may have their sidewalls correspondingly or respectively in contact with the first conductive patterns SSL1, WL11 to WL1n, and GSL1. Sidewall dielectric patterns SI may be correspondingly or respectively interposed between the first cell contact plugs CPLG1 and the first conductive patterns SSL1, WL11 to WL1n, and GSL1 positioned beneath the pad parts of the first conductive patterns SSL1, WL11 to WL1n, and GSL1. The first cell contact plugs CPLG1 may be portions of the first connection lines CL1 discussed with reference to FIG. 2.

The first peripheral contact plugs PPLG1 and the first input/output contact plugs IOPLG1 may be horizontally spaced apart from the first stack ST1 to be in a dielectric layer on the second connection region CNR2.

The first peripheral contact plugs PPLG1 may electrically connect the first common source line CSL1 to the second bonding pads BP2 via the lower conductive lines. The first peripheral contact plugs PPLG1 may be electrically connected to the CSL voltage controller 5 of the peripheral circuit structure PS. The first peripheral contact plugs PPLG1 may be portions of the first source connection line CL3a discussed with reference to FIG. 2.

Each of the first cell, peripheral, and input/output contact plugs CPLG1, PPLG1, and IOPLG1 may include a barrier metal layer including conductive metal nitride (e.g., titanium nitride or tantalum nitride) and a metal layer including metal (e.g., tungsten, titanium, or tantalum).

On the first connection region CNR1, first lower conductive lines may be coupled through contact plugs to the first cell contact plugs CPLG1. On the cell array region CAR, second lower conductive lines may be connected through contact plugs to the first bit lines BL1. On the second connection region CNR2, third lower conductive lines may be coupled through contact plugs to the first peripheral contact plugs PPLG1.

On the first connection region CNR1, first upper conductive lines may be coupled through contact plugs to the first cell contact plugs CPLG1. On the cell array region CAR, second upper conductive lines may be coupled through contact plugs to the first bit lines BL1. On the second connection region CNR2, third upper conductive lines may be coupled through contact plugs to the first peripheral contact plugs PPLG1.

The first, second, and third lower and upper conductive lines may include, for example, a metal (e.g., tungsten, copper, or aluminum), conductive metal nitride (e.g., titanium nitride or tantalum nitride), and transition metal (e.g., titanium or tantalum).

The second bonding pads BP2 may be provided in a lowermost dielectric layer of the first cell array structure CS1. The second bonding pads BP2 may be electrically connected to the first bit lines BL1, the first conductive patterns SSL1, WL11 to WL1n, and GSL1, and the first common source line CSL1. A surface of the lowermost dielectric layer may be in direct contact with that of the uppermost dielectric layer of the peripheral circuit structure PS.

A bonding method may be employed to electrically and physically connect the second bonding pads BP2 to the first bonding pads BP1. For example, the second bonding pads BP2 may be in direct contact with the first bonding pads BP1. The second bonding pads BP2 may have substantially the same shape, width, and area as those of the first bonding pads BP1.

The second bonding pads BP2 may include the same metallic material as that of the first bonding pads BP1. The second bonding pads BP2 may be formed of, for example, copper.

The third bonding pads BP3 may be provided in an uppermost dielectric layer of the first cell array structure CS1 to stand opposite to the second bonding pads BP2. The third bonding pads BP3 may be electrically connected to the first, second, and third upper conductive lines. The third bonding pads BP3 may be formed of, for example, copper.

The second cell array structure CS2 may be disposed on the first cell array structure CS1. The second cell array structure CS2 may include second memory cell strings CSTR2 including second memory cells MC2 that are three-dimensionally arranged as discussed with reference to FIG. 3.

The second cell array structure CS2 may include a second common source line CSL2, a second stack ST2, second vertical structures VS2, second bit lines BL2, second cell contact plugs CPLG2, second peripheral contact plugs PPLG2, and second input/output contact plugs IOPLG2. In addition, the second cell array structure CS2 may further include fourth bonding pads BP4 bonded to the third bonding pads BP3.

The second stack ST2 may include second conductive patterns SSL2, WL21 to WL2n, and GSL2 and second interlayer dielectric layers that are alternately stacked along a direction perpendicular to the top surface of the substrate 100. The second stack ST2 may include substantially the same structure and material as that of the first stack ST1.

The second stack ST2 may be disposed between separation structures SS that extend in parallel along one direction. The separation structures SS may include a dielectric material, such as silicon oxide. The second stack ST2 of the second cell array structure CS2 may be provided in plural, and the plurality of second stacks ST2 may extend in parallel along one direction.

The second conductive patterns SSL2, WL21 to WL2n, and GSL2 of the second stack ST2 may be stacked to have a stepwise structure on the second connection region CNR2. The second stack ST2 may be disposed to be mirror-symmetric with the first stack ST1. For example, the second conductive patterns SSL2, WL21 to WL2n, and GSL2 may have their lengths that increase with increasing distance from the peripheral circuit structure PS.

Each of the second conductive patterns SSL2, WL21 to WL2n, and GSL2 may have a pad part on the second connection region CNR2. The pad parts of the second conductive patterns SSL2, WL21 to WL2n, and GSL2 may be located at positions that are horizontally and vertically different from each other. The pad parts of the second conductive patterns SSL2, WL21 to WL2n, and GSL2 may vertically overlap the pad parts of the first conductive patterns SSL1, WL11 to WL1n, and GSL1. The second cell contact plugs CPLG2 may be correspondingly or respectively coupled to the pad parts of the second conductive patterns SSL2, WL21 to WL2n, and GSL2.

The number of stacked second conductive patterns SSL2, WL21 to WL2n, and GSL2 of the second stack ST2 may be the same as that of stacked first conductive patterns SSL1, WL11 to WL1n, and GSL1 of the first stack ST1. When viewed in one direction, a maximum length of the second conductive patterns SSL2, WL21 to WL2n, and GSL2 may be substantially the same as that of the first conductive patterns SSL1, WL11 to WL1n, and GSL1.

On the cell array region CAR, a plurality of second vertical structures VS2 may vertically penetrate or extend into the second stack ST2. The second vertical structures VS2 may include substantially the same structure and material as that of the first vertical structures VS1.

When viewed in plan, the second vertical structures VS2 may be arranged in a straight or zigzag fashion along one direction. Each of the second vertical structures VS2 may include a vertical channel formed of a semiconductor material. Each of the second vertical structures VS2 may include a lower part that penetrates or extends into a lower portion of the second stack ST2 and an upper part that penetrates or extends into an upper portion of the second stack ST2. Each of the lower and upper portions of the second stack ST2 may have a width that gradually decreases with increasing distance from the substrate 100.

According to some embodiments, when viewed in a cross section, the first and second cell array structures CS1 and CS2 may be bonded to each other such that the first common source line CSL1 of the first cell array structure CS1 are adjacent to the second common source line CSL2 of the second cell array structure CS2.

The second common source line CSL2 may be disposed in a vertical direction between the second stack ST2 and the fourth bonding pads BP4. The second common source line CSL2 may be in direct contact with bottom surfaces of the second vertical structures VS2. The second common source line CSL2 may be electrically connected through the second peripheral contact plugs PPLG2 to the fourth bonding pads BP4. The second peripheral contact plugs PPLG2 may be portions of the second source connection line CL3b discussed with reference to FIG. 2.

The second bit lines BL2 may be disposed on an uppermost second interlayer dielectric layer of the second stack ST2. Each of the second bit lines BL2 may be electrically connected to the second vertical structures VS2 arranged along an extension direction thereof. The second bit lines BL2 may be electrically connected through second lower conductive lines to the fourth bonding pads BP4.

Second upper and lower conductive lines may be disposed in upper and lower portions of the second stack ST2. The second lower conductive lines disposed in the lower portion of the second stack ST2 may be electrically connected to the fourth bonding pads BP4, and the second upper conductive lines disposed in the upper portion of the second stack ST2 may be electrically connected to the second cell contact plugs CPLG2, the second peripheral contact plugs PPLG2, and the second input/output contact plugs IOPLG2.

On the first connection region CNR1, the second cell contact plugs CPLG2 may penetrate or extend into the second stack ST2 to be correspondingly or respectively coupled to the pad parts of the second conductive patterns SSL2, WL21 to WL2n, and GSL2. The second cell contact plugs CPLG2 may have substantially the same vertical length.

On the first connection region CNR1, the second cell contact plugs CPLG2 may correspondingly or respectively vertically penetrate or extend into the pad parts of the second conductive patterns SSL2, WL21 to WL2n, and GSL2. The second cell contact plugs CPLG2 may electrically connect the second conductive patterns SSL2, WL21 to WL2n, and GSL2 to the fourth bonding pads BP4. The second cell contact plugs CPLG2 may be correspondingly or respectively connected to the first cell contact plugs CPLG1. The second cell contact plugs CPLG2 may vertically overlap the first cell contact plugs CPLG1. The second cell contact plugs CPLG2 may be portions of the first connection lines CL1 discussed with reference to FIG. 2.

The first conductive patterns SSL1, WL11 to WL1n, and GSL1 of the first stack ST1 may be one-to-one connected through the first and second cell contact plugs CPLG1 and CPLG2 to the second conductive patterns SSL2, WL21 to WL2n, and GSL2 of the second stack ST2. The first word lines WL11 to WL1n of the first stack ST1 and the second word lines WL21 to WL2n of the second stack ST2 may be connected to each other to be controlled in common. The first string selection lines SSL1 of the first stack ST1 and the second string selection lines SSL2 of the second stack ST2 may be connected to each other to be controlled in common. The first ground selection lines GSL1 of the first stack ST1 and the second ground selection lines GSL2 of the second stack ST2 may be connected to each other to be controlled in common.

The second cell contact plugs CPLG2 may have their sidewalls correspondingly in contact with the second conductive patterns SSL2, WL21 to WL2n, and GSL2. Sidewall dielectric patterns SI may be correspondingly or respectively interposed between the second cell contact plugs CPLG2 and the second conductive patterns SSL2, WL21 to WL2n, and GSL2 positioned beneath the pad parts of the second conductive patterns SSL2, WL21 to WL2n, and GSL2.

Input/output pads IOPAD may be disposed on an uppermost dielectric layer of the second cell array structure CS2. The uppermost dielectric layer of the second cell array structure CS2 may be provided thereon with a passivation layer having an opening that exposes a portion of the input/output pad IOPAD. The passivation layer may include a polyimide-based material, such as photosensitive polyimide (PSPI).

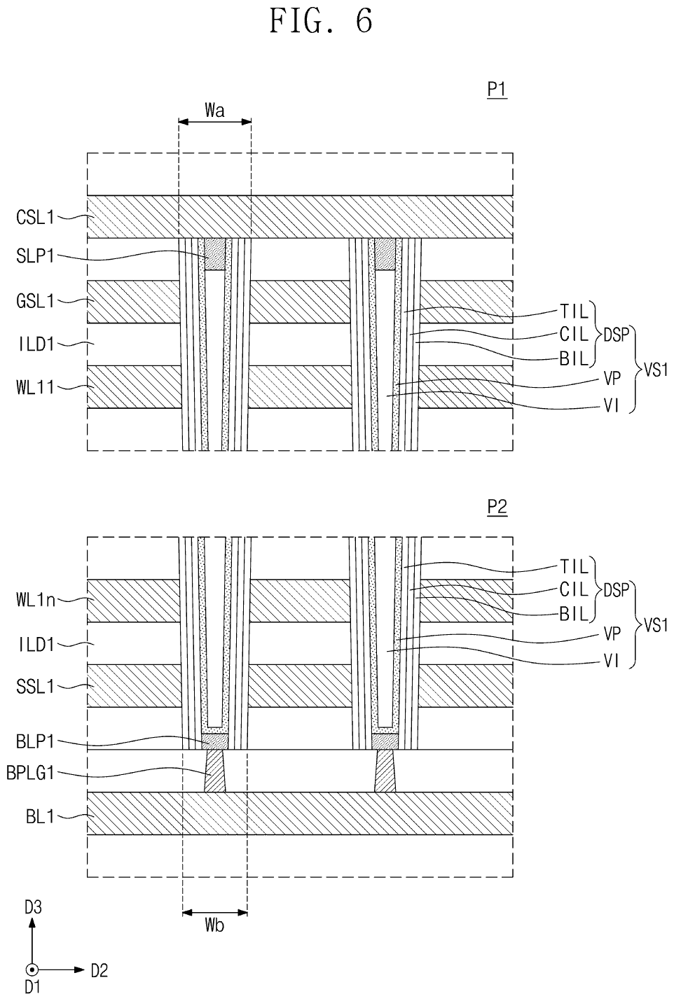

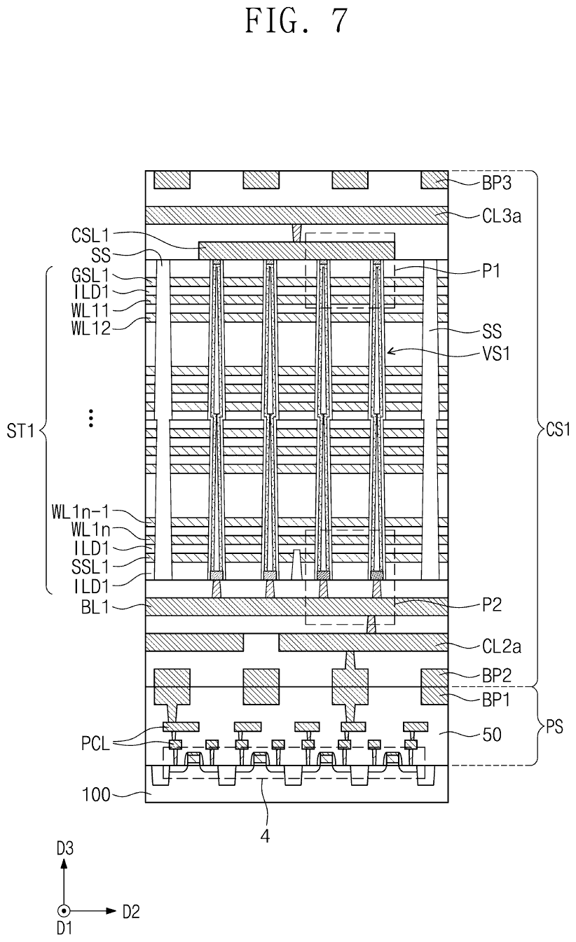

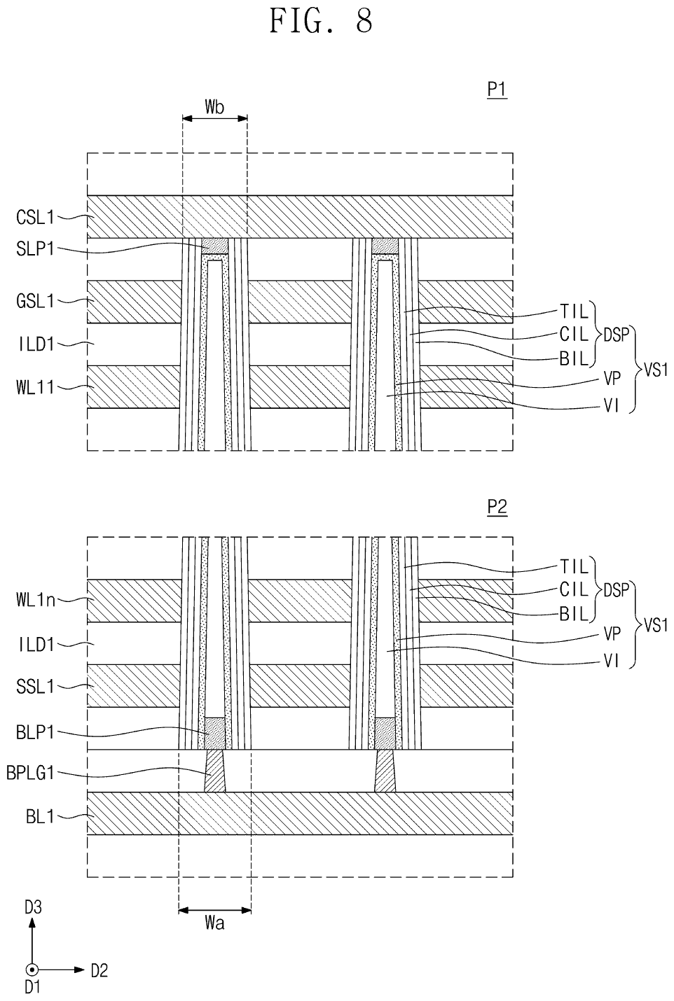

FIG. 5 illustrates a cross-sectional view partially showing a semiconductor memory device according to some embodiments of the present disclosure. FIG. 6 illustrates an enlarged view showing sections P1 and P2 of FIG. 5. FIG. 7 illustrates a cross-sectional view partially showing a semiconductor memory device according to some embodiments of the present disclosure. FIG. 8 illustrates an enlarged view showing sections P1 and P2 of FIG. 7.

FIGS. 5 and 7 depict cross-sections of a peripheral circuit structure and a first cell array structure on a cell array region depicted in FIG. 4.

Referring to FIGS. 5 and 7, a peripheral circuit structure PS may include, on a substrate 100, peripheral circuit lines PCL electrically connected to peripheral circuits or the row decoder 3, the page buffer 4, and the CSL voltage controller 5 discussed with reference to FIG. 1, and may also include first bonding pads BP1 electrically connected to the peripheral circuit lines PCL and a peripheral circuit dielectric layer 50 that at least partially surrounds the peripheral circuit lines PCL and the first bonding pads BP1.

For example, the peripheral circuits may include NMOS and PMOS transistors. The peripheral circuit lines PCL may be electrically connected through peripheral contact plugs to the peripheral circuits.

The peripheral circuit dielectric layer 50 may not cover or overlap top surfaces of the first bonding pads BP1. A top surface of the peripheral circuit dielectric layer 50 may be substantially coplanar with those of the first bonding pads BP1. The first bonding pads BP1 may be electrically connected to the peripheral circuits through the peripheral circuit lines PCL and the peripheral contact plugs.

The peripheral circuit structure PS may be provided thereon with a first cell array structure CS1 including second bonding pads BP2 and third bonding pads BP3 opposite to the second bonding pads BP2. As discussed above, the first cell array structure CS1 may include a first bit line BL1, a first common source line CSL1, and a first stack ST1.

The first stack ST1 may be disposed in a vertical direction between the first bit line BL1 and the first common source line CSL1. The first stack ST1 may include first conductive patterns SSL1, WL11 to WL1n, and GSL1 and first interlayer dielectric layers ILD1 that are alternately stacked along a direction perpendicular to a top surface of the substrate 100.

The first bit lines BL1 may be disposed between the first stack ST1 and the second bonding pads BP2, and may be electrically connected to the second bonding pads BP2 through first bit-line connection lines CL2a.

The first common source line CSL1 may be disposed on an uppermost first interlayer dielectric layer ILD1, and may be in direct contact with top surfaces of first vertical structures VS1. The first common source line CSL1 may be connected to first source connection lines CL3a.

In some embodiments, each of the first vertical structures VS1 may be provided in a vertical channel hole that penetrates or extends into the first stack ST1. In some embodiments, the vertical channel hole may include first vertical channel holes that penetrate or extend into a lower portion of the first stack ST1 and second vertical channel holes that penetrate or extend into an upper portion of the first stack ST1 and connect with the first vertical channel holes.

Each of the first vertical structures VS1 may include a first vertical extension in the first vertical channel hole and a second vertical extension in the second vertical channel hole. The first vertical extension and the second vertical extension may be a single structure that extends continuously without an interface. The first vertical extension may have a sidewall whose slope is uniform from bottom to upper portions thereof. Likewise, the second vertical extension may have a sidewall whose slope is uniform from lower to upper portions thereof.

As illustrated in FIGS. 5 and 6, each of the first and second vertical extensions may have a width that increases with increasing distance from the substrate 100. Thus, each of the first vertical structures VS1 may have a maximum width Wa on the top surface thereof and a minimum width Wb on a bottom surface thereof.

Alternatively, referring to FIGS. 7 and 8, each of the first and second vertical extensions may have a width that decreases with increasing distance from the substrate 100. Therefore, each of the first vertical structures VS1 may have a minimum width Wb on the top surface thereof and a maximum width Wa on a bottom surface thereof.

Referring to FIGS. 6 and 8, each of the first vertical structures VS1 may include a vertical channel VP, a vertical dielectric pillar VI, and a data storage pattern DSP.

The vertical channel VP may have a cylindrical shape (e.g., a macaroni shape or a pipe shape whose top and bottom ends are closed). The vertical channel VP may have an inner sidewall that defines an internal space and an outer sidewall adjacent to the first stack ST1. The vertical channel VP may at least partially surround an outer sidewall of the vertical dielectric pillar VI.

The vertical channel VP may include a semiconductor material, such as silicon (Si), germanium (Ge), or a mixture thereof. The vertical channel VP including a semiconductor material may be used as channels of the transistors SST1, SST2, MCT1, MCT2, GST1, and GST2 discussed with reference to FIG. 1.

As shown in FIGS. 6 and 8, the vertical channel VP may have a first source conductive pad SLP1 on a top end thereof and a first bit-line conductive pad BLP1 on a bottom end thereof. The first source conductive pad SLP1 and the first bit-line conductive pad BLP1 may be formed of an impurity-undoped semiconductor material, an impurity-doped semiconductor material, or a conductive material.

The first source conductive pad SLP1 may be in direct contact with the first common source line CSL1. The first bit-line conductive pad BLP1 may be connected through a bit-line contact plug BPLG1 to the first bit line BL1.

The data storage pattern DSP may extend in a vertical direction and may at least partially surround the outer sidewall of each vertical channel VP. The data storage pattern DSP may have a cylindrical shape (e.g., a macaroni shape or a pipe shape whose top and bottom ends are opened). The data storage pattern DSP may be formed of a single thin layer or a plurality of thin layers. In some embodiments of the present disclosure, the data storage pattern DSP may include a tunnel dielectric layer TIL, a charge storage layer CIL, and a blocking dielectric layer BIL that sequentially stacked on the outer sidewall of the vertical channel VP, which layers TIL, CIL, and BIL constitute a data storage layer of a NAND Flash memory device. For example, the charge storage layer CIL may be a trap dielectric layer, a floating gate electrode, or a dielectric layer including conductive nano-dots.

These features of the first vertical structures VS1 may applicable to the second vertical structures VS2 discussed with reference to FIG. 4, and as such, the discussion thereof is omitted for brevity.

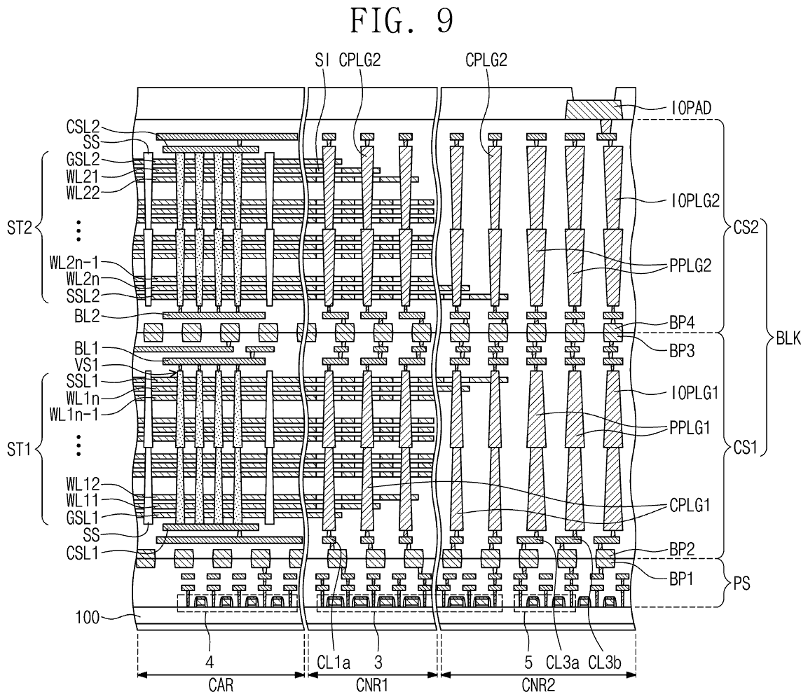

FIG. 9 illustrates a cross-sectional view showing a semiconductor memory device according to some embodiments of the present disclosure. A description of the same technical features as those of the embodiments mentioned above with reference to FIG. 4 will be omitted for brevity of explanation, and a difference thereof will be discussed in detail.

Referring to FIG. 9, a semiconductor memory device according to some embodiments may include a peripheral circuit structure PS on a substrate 100 and a memory block BLK on the peripheral circuit structure PS, and the memory block BLK may include a first cell array structure CS1 and a second cell array structure CS2 on the first cell array structure CS1.

A first stack ST1 of the first cell array structure CS1 may include first conductive patterns SSL1, WL11 to WL1n, and GSL1 that are vertically stacked. The first conductive patterns SSL1, WL11 to WL1n, and GSL1 may have their lengths that increase with increasing distance from the substrate 100.

A second stack ST2 of the second cell array structure CS2 may include second conductive patterns SSL2, WL21 to WL2n, and GSL2 that are vertically stacked. The second conductive patterns SSL2, WL21 to WL2n, and GSL2 may have their lengths that decrease with increasing distance from the substrate 100.

The number of stacked second conductive patterns SSL2, WL21 to WL2n, and GSL2 of the second stack ST2 may be the same as that of stacked first conductive patterns SSL1, WL11 to WL1n, and GSL1 of the first stack ST1. When viewed in one direction, a maximum length of the second conductive patterns SSL2, WL21 to WL2n, and GSL2 may be substantially the same as that of the first conductive patterns SSL1, WL11 to WL1n, and GSL1.

When viewed in a cross section, the first and second cell array structures CS1 and CS2 may be bonded to each other to allow first bit lines BL1 of the first cell array structure CS1 to be vertically adjacent to second bit lines BL2 of the second cell array structure CS2.

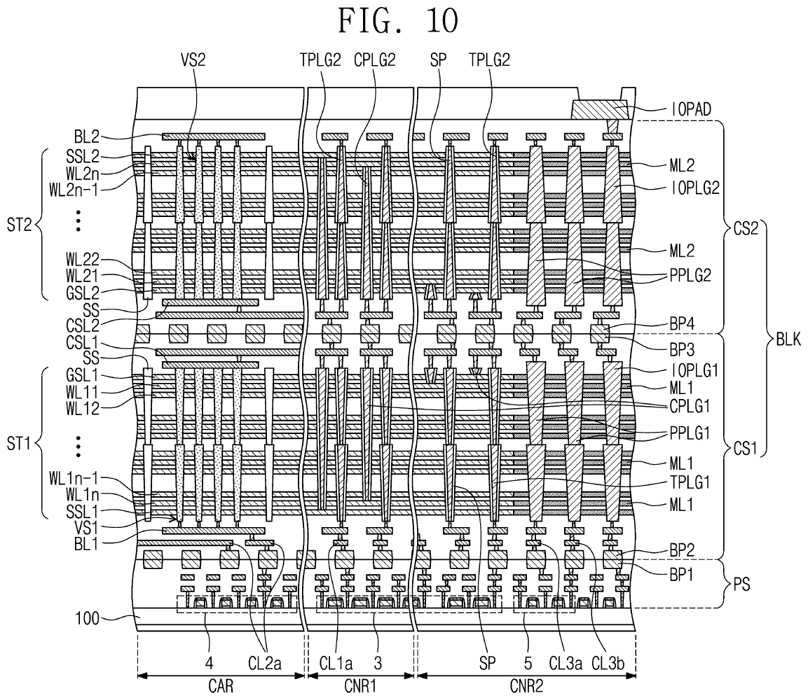

FIG. 10 illustrates a cross-sectional view showing a semiconductor memory device according to some embodiments of the present disclosure. A description of the same technical features as those of the embodiments mentioned above with reference to FIG. 4 will be omitted for brevity of explanation, and a difference thereof will be discussed in detail.

Referring to FIG. 10, a semiconductor memory device according to some embodiments may include a peripheral circuit structure PS on a substrate 100 and a memory block BLK on the peripheral circuit structure PS, and the memory block BLK may include a first cell array structure CS1 and a second cell array structure CS2 on the first cell array structure CS1.

The first cell array structure CS1 may include a first common source line CSL1, a first stack ST1, first vertical structures VS1, first bit lines BL1, first cell contact plugs CPLG1, first through plugs TPLG1, first peripheral contact plugs PPLG1, and first input/output contact plugs IOPLG1. In addition, the first cell array structure CS1 may further include second bonding pads BP2 bonded to first bonding pads BP1 and third bonding pads BP3 opposite to the second bonding pads BP2.

According to the embodiment shown in FIG. 10, the first stack ST1 of the first cell array structure CS1 may include first conductive patterns SSL1, WL11 to WL1n, and GSL1 that are vertically stacked and first mold patterns ML1 located at the same level as that of the first conductive patterns SSL1, WL11 to WL1n, and GSL1.

The first conductive patterns SSL1, WL11 to WL1n, and GSL1 may continuously extend from a cell array region CAR to a first connection region CNR1, and may have substantially the same length. The first mold patterns ML1 may be correspondingly located at the same level as that of the first conductive patterns SSL1, WL11 to WL1n, and GSL1, and may be in contact with sidewalls of the first conductive patterns SSL1, WL11 to WL1n, and GSL1. The first mold patterns ML1 may include a dielectric material (e.g., silicon nitride) different from the first interlayer dielectric layers ILD1 discussed above.

On the first connection region CNR1, the first cell contact plugs CPLG1 may penetrate or extend into a portion of the first stack ST1 to be correspondingly or respectively coupled to the first conductive patterns SSL1, WL11 to WL1n, and GSL1. The first cell contact plugs CPLG1 may be in direct contact with top surfaces of the first conductive patterns SSL1, WL11 to WL1n, and GSL1.

The first cell contact plugs CPLG1 may have different vertical lengths, and the vertical lengths of the first cell contact plugs CPLG1 may decrease or increase with increasing distance from the cell array region CAR. The first cell contact plugs CPLG1 may have their bottom surfaces located at different levels and their top surfaces located at the same level.

On the first connection region CNR1, the first through plugs TPLG1 may vertically penetrate or extend into an entirety of the first stack ST1 to be coupled to first lower conductive lines. The first through plugs TPLG1 may be correspondingly connected through connection patterns CP to the first cell contact plugs CPLG1.

Dielectric spacers SP may correspondingly surround outer sidewalls of the first cell contact plugs CPLG1 and outer sidewalls of the first through plugs TPLG1. The dielectric spacers SP may be disposed between the first cell contact plugs CPLG1 and the first stack ST1 and between the first through plugs TPLG1 and the first stack ST1. The dielectric spacer SP may include at least one selected from silicon oxide, silicon nitride, silicon oxynitride, and/or low-k dielectrics.

On a second connection region CNR2, the first peripheral contact plugs PPLG1 and the first input/output contact plugs IOPLG1 may vertically penetrate or extend into the first mold patterns ML1 of the first stack ST1.

The second cell array structure CS2 may include a second common source line CSL2, a second stack ST2, second vertical structures VS2, second bit lines BL2, second cell contact plugs CPLG2, second through plugs TPLG2, second peripheral contact plugs PPLG2, and second input/output contact plugs IOPLG2. In addition, the second cell array structure CS2 may further include fourth bonding pads BP4 bonded to the third bonding pads BP3.

The second cell array structure CS2 may have substantially the same features as that of the first cell array structure CS1.

The second common source line CSL2 of the second cell array structure CS2 may be adjacent to the first common source line CSL1 of the first cell array structure CS1. Alternatively, the second bit line BL2 of the second cell array structure CS2 may be adjacent to the first common source line CSL1 of the first cell array structure CS1.

The second stack ST2 may include second conductive patterns SSL2, WL21 to WL2n, and GSL2 that are vertically stacked and second mold patterns ML2 located at the same level as that of the second conductive patterns SSL2, WL21 to WL2n, and GSL2.

The second cell contact plugs CPLG2 may be disposed corresponding to the first cell contact plugs CPLG1, and the second through plugs TPLG2 may be disposed corresponding to the first through plugs TPLG1.

On the second connection region CNR2, the second peripheral contact plugs PPLG2 and the second input/output contact plugs IOPLG2 may vertically penetrate or extend into the second mold patterns ML2 of the second stack ST2.

The first and second cell contact plugs CPLG1 and CPLG2 and the first and second through contact plugs TPLG1 and TPLG2 may constitute first connection lines (see CL1 of FIG. 3) through which the first conductive patterns SSL1, WL11 to WL1n, and GSL1 of the first stack ST1 are one-to-one connected to the second conductive patterns SSL2, WL21 to WL2n, and GSL2 of the second stack ST2.

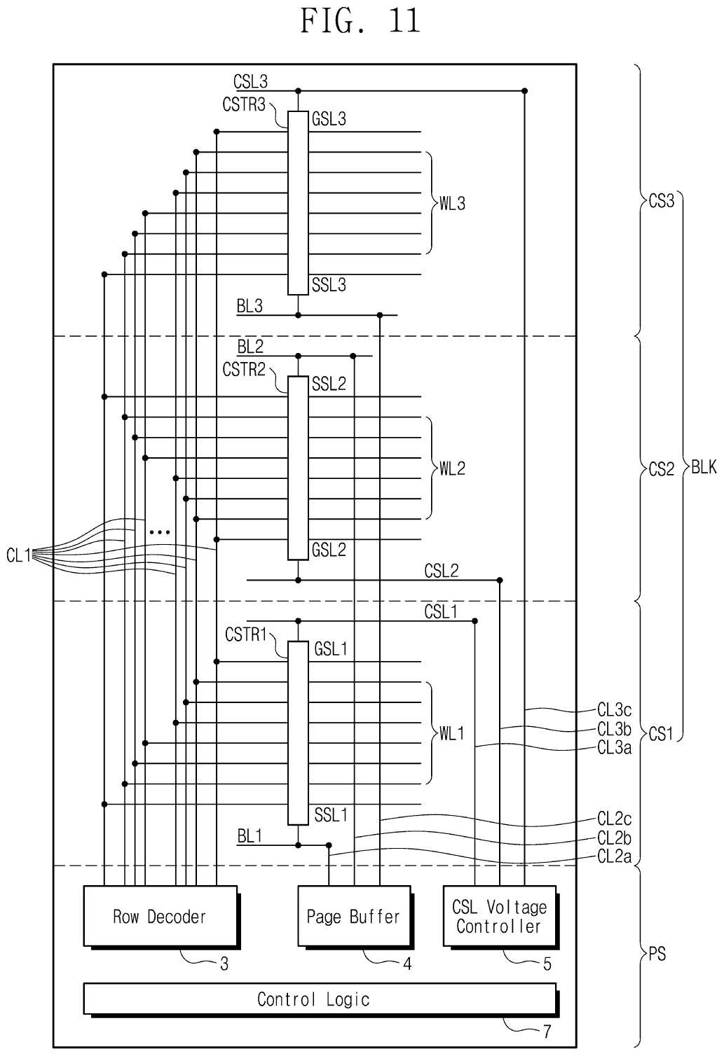

FIG. 11 illustrates a simplified circuit diagram showing a semiconductor memory device according to some embodiments of the present disclosure. A description of the same technical features as those of the embodiments mentioned above with reference to FIG. 2 will be omitted for brevity of explanation, and a difference thereof will be discussed in detail.

Referring to FIG. 11, a semiconductor memory device may include a peripheral circuit structure PS and a memory block BLK on the peripheral circuit structure PS, and the memory block BLK may include first, second, and third cell array structures CS1, CS2, and CS3 that are vertically stacked. The third cell array structure CS3 may be bonded and connected to the second cell array structure CS2 discussed above with reference to FIG. 2.

The third cell array structure CS3 may include a third bit line BL3, a third string selection line SSL3, third word lines WL3, a third ground selection line GSL3, a third common source line CSL3, and a third memory cell string CSTR3. In the third cell array structure CS3, the third memory cell string CSTR3 may be provided in plural.

The third word lines WL3 of the third cell array structure CS3 may be connected to the first and second word lines WL1 and WL2 through the first connection lines CL1, thereby being connected to the row decoder 3.

The third string selection line SSL3 of the third cell array structure CS3 may be connected in common to the first and second string selection lines SSL1 and SSL2 through the first connection lines CL1, thereby being connected to the row decoder 3. The first, second, and third string selection lines SSL1, SSL2, and SSL3 may be separated and controlled independently of each other.

The third ground selection line GSL3 of the third cell array structure CS3 may be connected in common to the first and second ground selection lines GSL1 and GSL2 through the first connection lines CL1, thereby being connected to the row decoder 3. The first, second, and third ground selection lines GSL1, GSL2, and GSL3 may be separated and controlled independently of each other.

The third bit lines BL3 of the third cell array structure CS3 may be connected to the page buffer 4 through a third bit-line connection line CL2c, and the third common source line CSL3 of the third cell array structure CS3 may be connected to the CSL voltage controller 5 through a third source connection line CL3c.

The third common source line CSL3 of the third cell array structure CS3 may be disposed vertically adjacent to the second bit lines BL2 of the second cell array structure CS2. Alternatively, the third bit lines BL3 of the third cell array structure CS3 may be vertically adjacent to the second bit lines BL2 of the second cell array structure CS2.

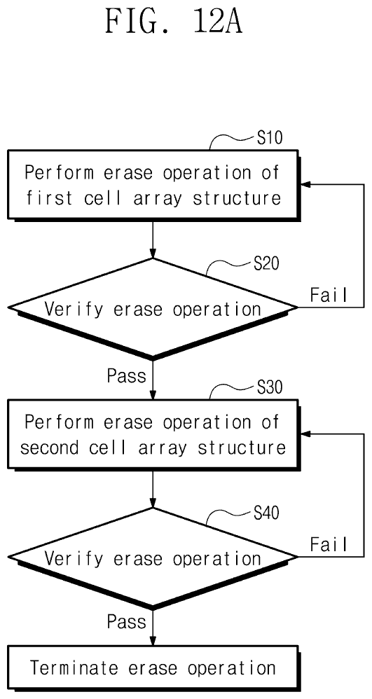

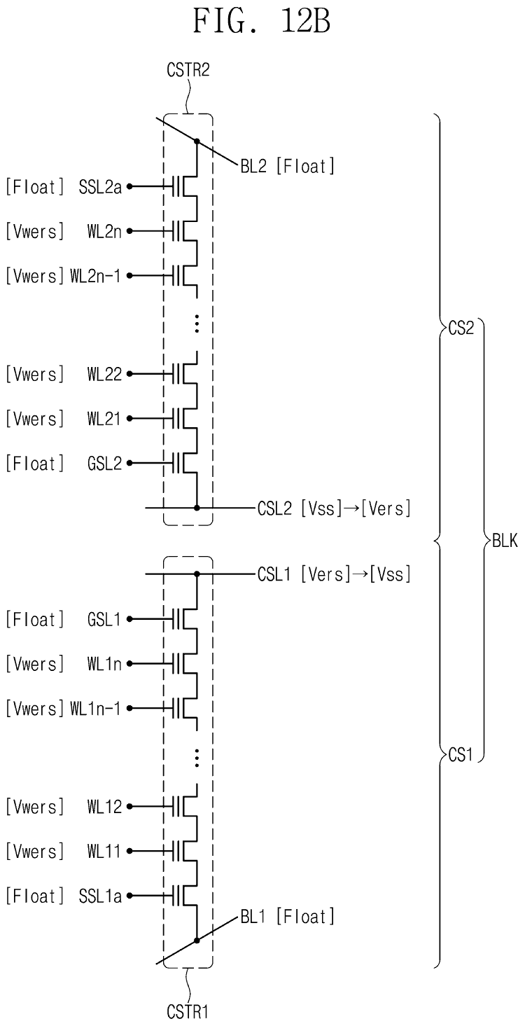

FIG. 12A illustrates a flow chart showing an erase operation of a semiconductor memory device according to some embodiments of the present disclosure. FIG. 12B illustrates a circuit diagram showing a bias condition in an erase operation of a semiconductor memory device according to some embodiments of the present disclosure.

Referring to FIGS. 12A and 12B, as discussed above, the first and second cell array structures CS1 and CS2 included in the memory block BLK may be manufactured separately on different wafers and then connected to each other by a bonding manner. Therefore, memory cells of the first cell array structure CS1 and memory cells of the second cell array structure CS2 may have different threshold voltage distributions. Thus, an erase operation of the semiconductor memory device may be independently performed on the first and second cell array structures CS1 and CS2. In some embodiments, in a program, read, or erase operation of the first and second cell array structures CS1 and CS2, the first word lines WL11 to WL1n may be correspondingly connected to the second word lines WL21 to WL2n.

For example, a first erase operation may be performed on the first cell array structure CS1 (S10).

In the first erase operation, an erase voltage Vers may be applied to the first common source line CSL1, and a ground voltage Vss (or 0 V) may be applied to the second common source line CSL2.

In the first erase operation, a word-line erase voltage Vwers may be applied to the word lines WL11 to WL1n and WL21 to WL2n of the first and second cell array structures CS1 and CS2. The word-line erase voltage Vwers may be a ground voltage or 0 V. A difference in voltage between the erase voltage Vers and the word-line erase voltage Vwers may induce tunneling (e.g., Fowler-Nordheim tunneling) in memory cells of the first cell array structure CS1, and data in the memory cells of the first cell array structure CS1 may be erased while holes are injected into a charge storage layer. For example, a threshold voltage of the memory cells of the first cell array structure CS1 may be reduced to a voltage level of an erase state.

Afterwards, an erase verification operation may be performed on the memory cells of the first cell array structure CS1 (S20).

In the erase verification operation, the memory cells of the first cell array structure CS1 may be provided with an erase verification voltage to confirm whether the memory cells are erased. When the threshold voltage of the memory cell is equal to or less than the erase verification voltage, a semiconductor memory device may be determined to be erased normally and thus the first erase operation may be terminated.

An erase loop where the first erase operation and the erase verification operation are performed may be repeatedly performed to complete erasure of the memory cells of the first cell array structure CS1.

After the completion of the first erase operation in the first cell array structure CS1, a second erase operation may be performed on the second cell array structure CS2 (S30). In the first and second erase operations, the same erase voltage may be applied to the first and second common source lines CSL1 and CSL2.

In the second erase operation, an erase voltage Vers may be applied to the second common source line CSL2, and a ground voltage Vss (or 0 V) may be applied to the first common source line CSL1.

In the second erase operation, a word-line erase voltage Vwers may be applied to the word lines WL11 to WL1n and WL21 to WL2n of the first and second cell array structures CS1 and CS2. A difference in voltage between the erase voltage Vers and the word-line erase voltage Vwers may induce tunneling (e.g., Fowler-Nordheim tunneling) in memory cells of the second cell array structure CS2, and data in the memory cells of the second cell array structure CS2 may be erased while holes are injected into a charge storage layer. For example, a threshold voltage of the memory cells of the second cell array structure CS2 may be reduced to a voltage level of an erase state.

Afterwards, an erase verification operation may be performed on the memory cells of the second cell array structure CS2 (S40).

In the erase verification operation, the memory cells of the second cell array structure CS2 may be provided with an erase verification voltage to confirm whether the memory cells are erased. When the threshold voltage of the memory cell is equal to or less than the erase verification voltage, a semiconductor memory device may be determined to be erased normally and thus the second erase operation may be terminated.

An erase loop where the first and second erase operations and the erase verification operation are performed may be repeatedly performed to complete erasure of the memory block BLK.

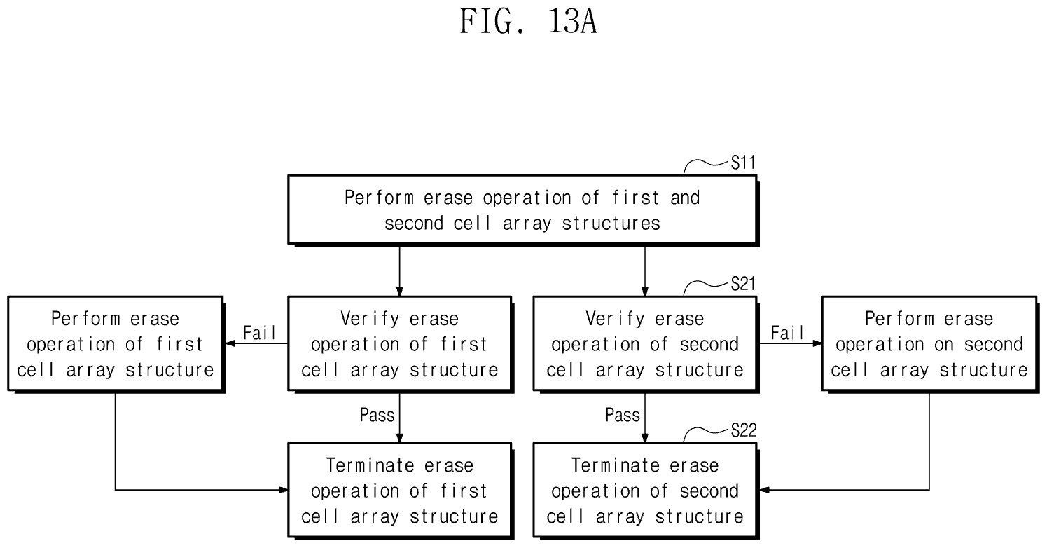

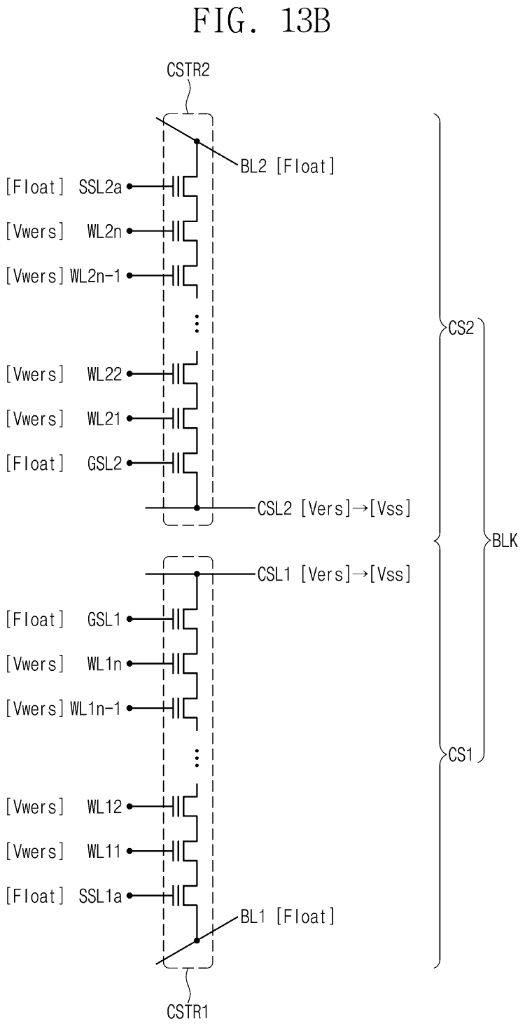

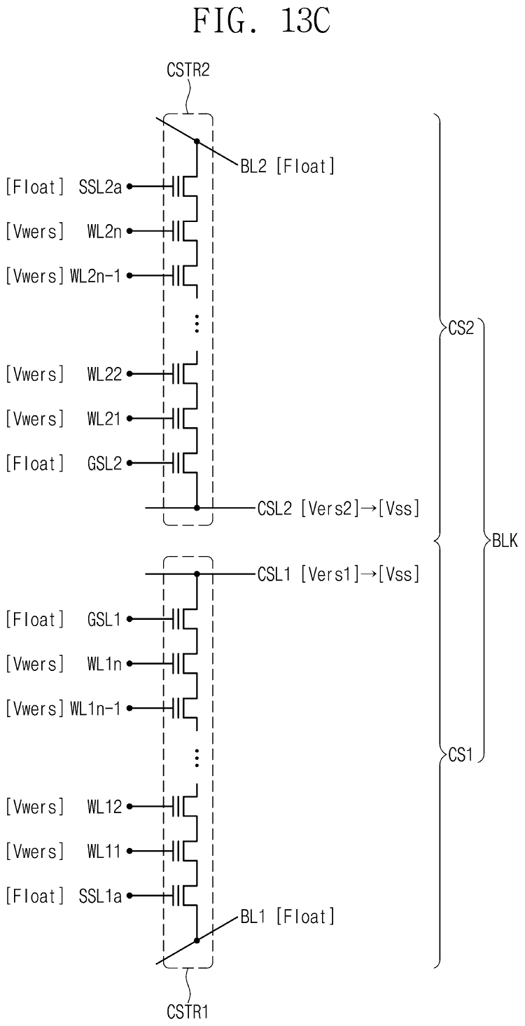

FIG. 13A illustrates a flow chart showing an erase operation of a semiconductor memory device according to some embodiments of the present disclosure. FIGS. 13B and 13C illustrate circuit diagrams showing a bias condition in an erase operation of a semiconductor memory device according to some embodiments of the present disclosure.

Referring to FIGS. 13A and 13B, an erase operation may be simultaneously performed on the first and second cell array structures CS1 and CS2 (S11). For example, an erase voltage Vers may be concurrently applied to the first and second common source lines CSL1 and CSL2.

Afterwards, an erase verification operation may be performed on memory cells of each of the first and second cell array structures CS1 and CS2 (S21).

When a threshold voltage of the memory cell of the first cell array structure CS1 is equal to or less than an erase verification voltage, an erase operation of the first cell array structure CS1 may be terminated (S22), and a ground voltage Vss may be applied to the first common source line CSL1.

When a threshold voltage of the memory cell of the second cell array structure CS2 is equal to or less than an erase verification voltage, an erase operation of the second cell array structure CS2 may be terminated (S22), and a ground voltage Vss may be applied to the second common source line CSL2.

As the memory cells of the first cell array structure CS1 and the memory cells of the second cell array structure CS2 have different threshold voltage distributions, the erase operations of the first and second cell array structures CS1 and CS2 may have different termination points.

Referring to FIGS. 13A and 13B, an erase operation may be simultaneously performed on the first and second cell array structures CS1 and CS2 (S11), and in this step, a first erase voltage Vers1 may be applied to the first common source line CSL1 and a second erase voltage Vers2 may be applied to the second common source line CSL2. In some embodiments, as the memory cells of the first cell array structure CS1 and the memory cells of the second cell array structure CS2 have different threshold voltage distributions, the second erase voltage Vers2 may be different from the first erase voltage Vers1.

After the completion of the erase operation of the first and second cell array structures CS1 and CS2, a ground voltage Vss may be applied to each of the first and second common source lines CSL1 and CSL2.

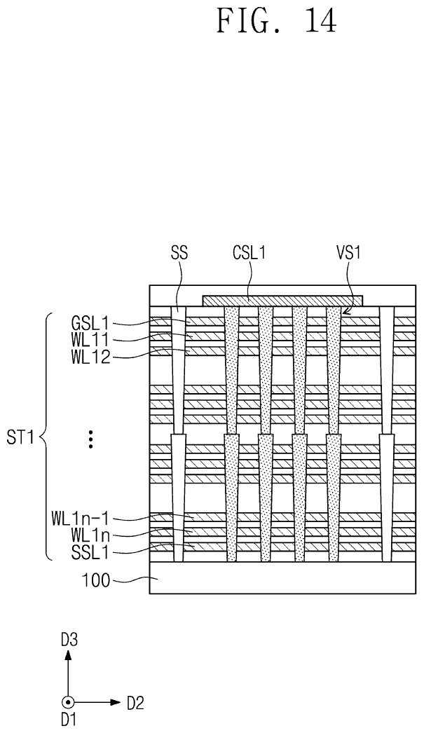

FIGS. 14 to 20 illustrate diagrams showing a method of fabricating a semiconductor memory device according to some embodiments of the present disclosure.

Referring to FIG. 14, on a first substrate 100, a first stack ST1 may be formed in which first conductive patterns are vertically stacked. The first stack ST1 may include a first ground selection line GSL1, first word lines WL11 to WL1n, and first string selection lines SSL1 that are vertically stacked.

The formation of the first stack ST1 may include vertically alternately stacking interlayer dielectric layers and sacrificial layers, forming trenches that penetrate or extend into the interlayer dielectric layers and the sacrificial layers to expose the first substrate 100, replacing the sacrificial layers exposed to the trenches with a conductive material to form first conductive patterns correspondingly or respectively between the interlayer dielectric layers, and filling or providing the trenches with a dielectric material to form separation structures SS.

A plurality of first vertical structures VS1 may be formed on the first substrate 100 to vertically penetrate or extend into the first stack ST1. Each of the first vertical structures VS1 may have a width that decreases with decreasing distance from a top surface of the first substrate 100.

The formation of the first vertical structures VS1 may include forming vertical channel holes that penetrate or extend into the first stack ST1 to expose the first substrate 100, sequentially depositing a data storage layer and a vertical channel layer in the vertical channel holes, and etching and planarizing the data storage layer and the vertical channel layer.

After that, first source conductive pads may be formed on top ends of the first vertical structures VS1. The first source conductive pads may be impurity doped regions or may be formed of a conductive material.

A first common source line CSL1 may be formed on the first stack ST1. The first common source line CSL1 may be formed by depositing a conductive layer on the first stack ST1 and patterning the conductive layer. The first common source line CSL1 may be in direct contact with top surfaces of the first vertical structures VS1 or with the first source conductive pads.

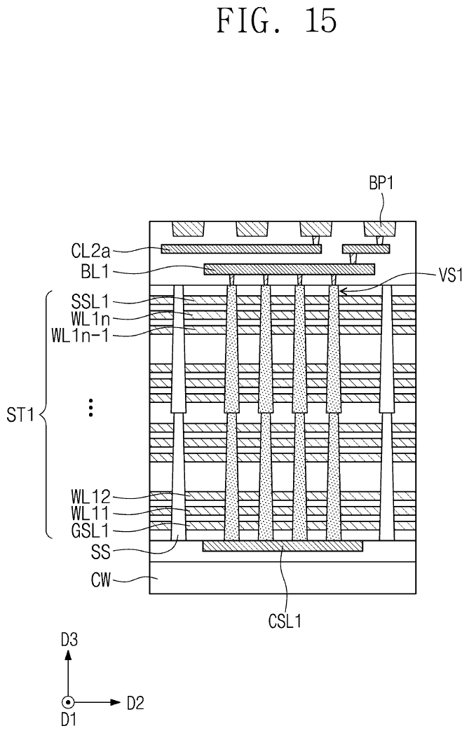

Referring to FIG. 15, after the formation of the first common source line CSL1, an adhesion layer may be used to attach a carrier substrate CW to a dielectric layer.

The carrier substrate CW may be a glass substrate or a semiconductor substrate. The adhesion layer may be, for example, a polymer tape including a dielectric material.

After the attachment of the carrier substrate CW, the first stack ST1 may be turned upside down. For example, the first substrate 100 may be positioned at a top position, and the first stack ST1 may be disposed to allow its stepwise structure to overturn.

The first substrate 100 may be removed. The first substrate 100 may be removed by one or more of a grinding process, a planarization process, a dry etching process, and a wet etching process. The removal of the first substrate 100 may expose a lowermost interlayer dielectric layer of the first stack ST1 and bottom surfaces of the first vertical structures VS1.

First bit-line conductive pads may be formed on bottom ends of the first vertical structures VS1. The first bit-line conductive pads may be impurity doped regions or may be formed of a conductive material.

First bit lines BL1 may be formed to run or extend across the first stack ST1 and to connect with the first vertical structures VS1. The first bit lines BL1 may be connected through bit-line contact plugs to the first bit-line conductive pads.

First bonding pads BP1 may be formed in an uppermost dielectric layer, and the first bonding pads BP1 may be electrically connected to first, second, and third connection lines.

A damascene process may be used to form the first bonding pads BP1. The first bonding pads BP1 may be formed of, for example, copper.

The first bonding pads BP1 may have their top surfaces substantially coplanar with that of the uppermost dielectric layer. In this description below, the phrase “substantially coplanar with” may mean that a planarization process can be performed. The planarization process may include, for example, a chemical mechanical polishing (CMP) process or an etch-back process.

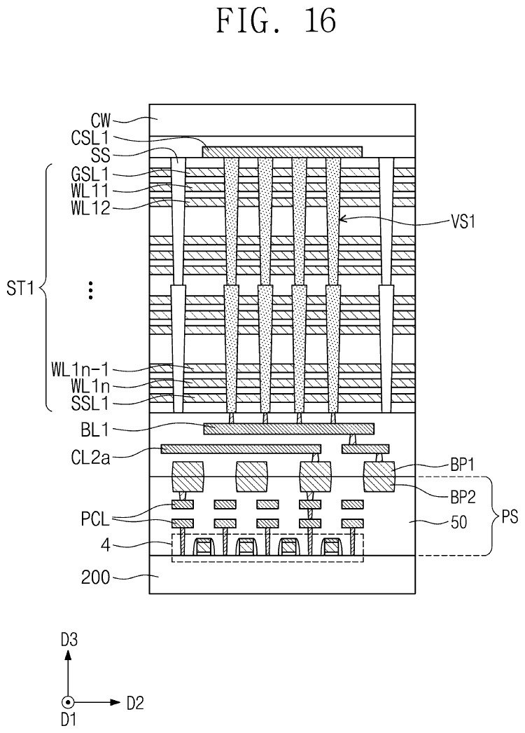

Referring to FIG. 16, a second substrate 200 may be provided thereon with a peripheral circuit structure PS in which peripheral circuits are integrated.

The peripheral circuit structure PS may be peripheral circuits, and row and column decoder, page buffers, and control circuits may be formed on the second substrate 200. The peripheral circuits may include metal oxide semiconductor (MOS) transistors each of which uses the second substrate 200 as a channel.

A peripheral circuit dielectric layer 50 may include a single dielectric layer or a plurality of stacked dielectric layers that cover or overlap the peripheral circuits. Peripheral circuit lines PCL connected to the peripheral circuits may be formed by depositing a conductive layer and patterning the conductive layer.

Second bonding pads BP2 may be formed in an uppermost dielectric layer of the peripheral circuit dielectric layer 50. The second bonding pads BP2 may be electrically connected to the peripheral circuits through the peripheral circuit lines PCL.

A damascene process may be used to form the second bonding pads BP2. The second bonding pads BP2 may have their top surfaces substantially coplanar with that of the peripheral circuit dielectric layer 50.

The first bonding pads BP1 on the carrier substrate CW may be bonded to the second bonding pads BP2 of the peripheral circuit structure PS. As the first bonding pads BP1 and the second bonding pads BP2 are bonded to each other, a structure on the first substrate 100 may be turned upside down. After the bonding of the first and second bonding pads BP1 and BP2, the carrier substrate CW may be removed.

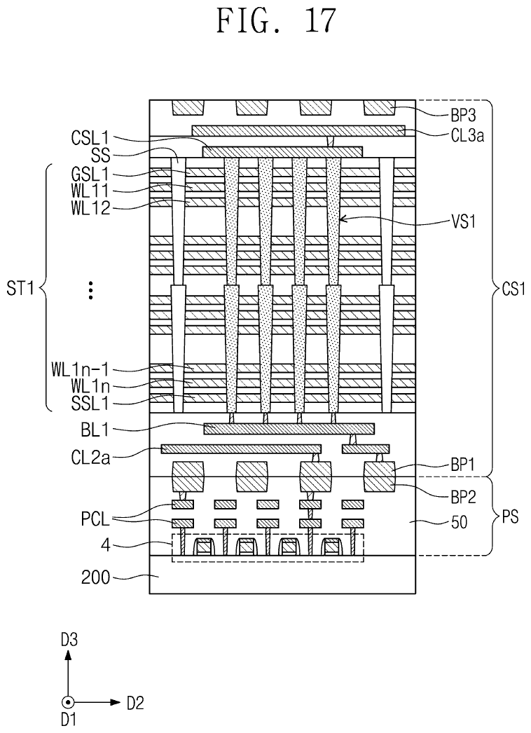

Referring to FIG. 17, first source connection lines CL3a may be formed, which are connected to the first common source line CSL1.

Third bonding pads BP3 may be formed in an uppermost dielectric layer, and the third bonding pads BP3 may be electrically connected to the first source connection lines CL3a.

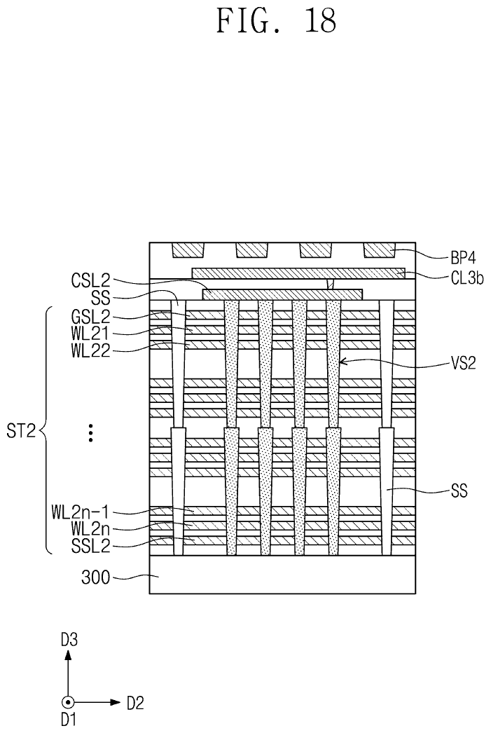

Referring to FIG. 18, a second stack ST2 may be formed on a third substrate 300, which second stack ST2 includes second conductive patterns SSL2, WL21 to WL2n, and GSL2 that are vertically stacked. The third substrate 300 may be a silicon substrate. The second stack ST2 may include second string selection lines SSL2, second word lines WL21 to WL2n, and a second ground selection line GSL2 that are vertically stacked. The formation of the second stack ST2 may be substantially the same as that of the first stack ST1.

A plurality of second vertical structures VS2 may be formed on the third substrate 300 to vertically penetrate or extend into the second stack ST2. Each of the second vertical structures VS2 may have a width that decreases with decreasing distance from a top surface of the third substrate 300. The formation of the second vertical structures VS2 may be substantially the same as that of the first vertical structures VS1 discussed above.

Second source conductive pads may be formed on top ends of the second vertical structures VS2. The second source conductive pads may be impurity doped regions or may be formed of a conductive material.

A second common source line CSL2 may be formed on the second stack ST2. The second common source line CSL2 may be formed by depositing a conductive layer on the second stack ST2 and patterning the conductive layer. The second common source line CSL2 may be in direct contact with top surfaces of the second vertical structures VS2 or with the second source conductive pads.

Second source connection lines CL3b may be formed, which are connected to the second common source line CSL2. In addition, on first and second connection regions (see CNR1 and CNR2 of FIG. 4), second cell contact plugs CPLG2, second peripheral contact plugs PPLG2, and second input/output contact plugs IOPLG2 may be formed to penetrate or extend into the second stack ST2. Then, fourth bonding pads BP4 may be formed in an uppermost dielectric layer.

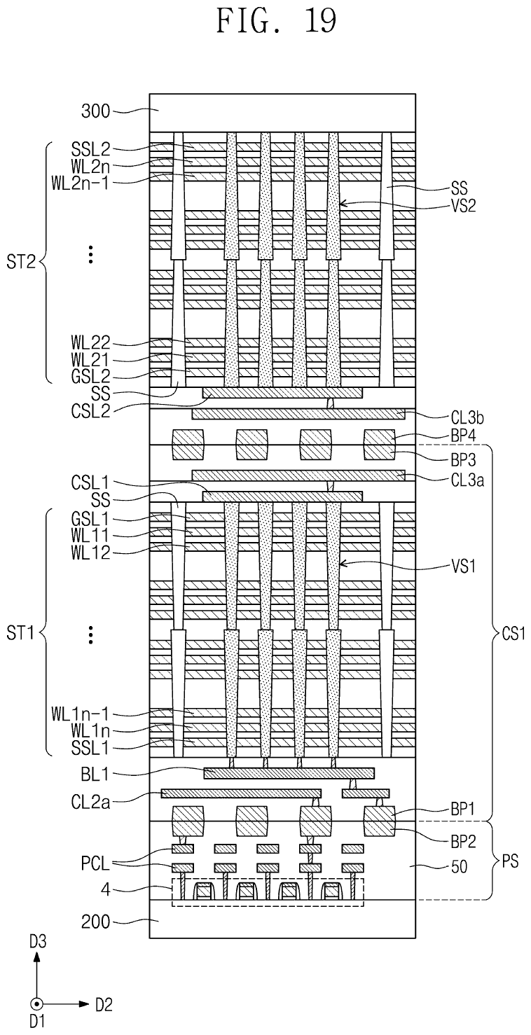

Referring to FIG. 19, the fourth bonding pads BP4 formed on the third substrate 300 may be bonded to the third bonding pads BP3 of the first cell array structure CS1. As the fourth bonding pads BP4 and the third bonding pads BP3 are bonded to each other, the second stack ST2 and the second vertical structures VS2 may be turned upside down.

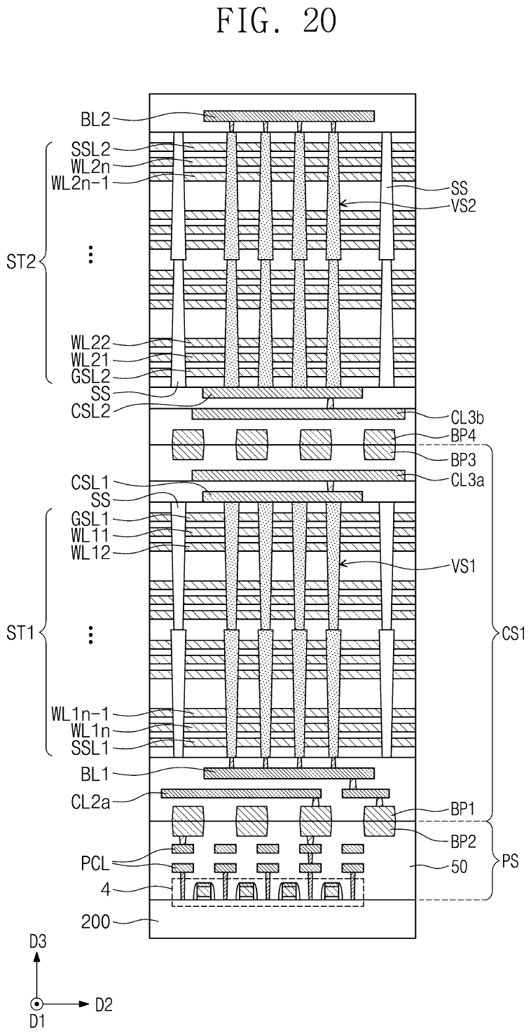

Referring to FIG. 20, after the bonding of the third and fourth bonding pads BP3 and BP4, the third substrate 300 may be removed. The third substrate 300 may be removed by one or more of a grinding process, a planarization process, a dry etching process, and a wet etching process. The removal of the third substrate 300 may expose an uppermost interlayer dielectric layer of the second stack ST2.

Second bit-line conductive pads may be formed on bottom ends of the second vertical structures VS2. The second bit-line conductive pads may be impurity doped regions or may be formed of a conductive material.

Second bit lines BL2 may be formed to connect with the second vertical structures VS2 and to run across the second stack ST2. The second bit line BL2 may be connected through bit-line contact plugs to the second bit-line conductive pads.

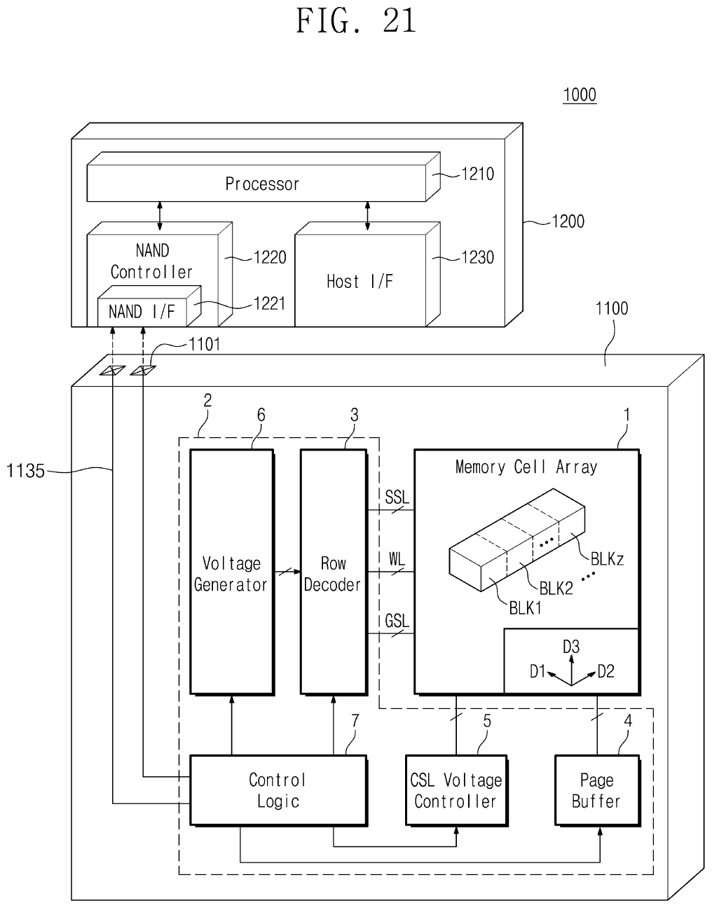

FIG. 21 illustrates a simplified diagram showing an electronic system including a semiconductor memory device according to some embodiments of the present disclosure.

Referring to FIG. 21, an electronic system 1000 according to some embodiments of the present disclosure may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. As discussed with reference to FIG. 1, the semiconductor device 1100 may include a memory cell array 1 and a peripheral circuit 2 that controls the memory cell array 1. The peripheral circuit 2 may include a row decoder 3, a page buffer 4, a CSL voltage controller 5, a voltage generator 6, and a control logic 7.

The semiconductor device 1100 may communicate with the controller 1200 through an input/output pad 1101 electrically connected to the control logic 7. The input/output pad 1101 may be electrically connected to the control logic 7 through an input/output connection line 1135.

The controller 1200 may include a processor 1210, a NAND controller 1220, and a host interface 1230. According to some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on memory cells of the semiconductor device 1100, and/or data intended to be read from memory cells of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

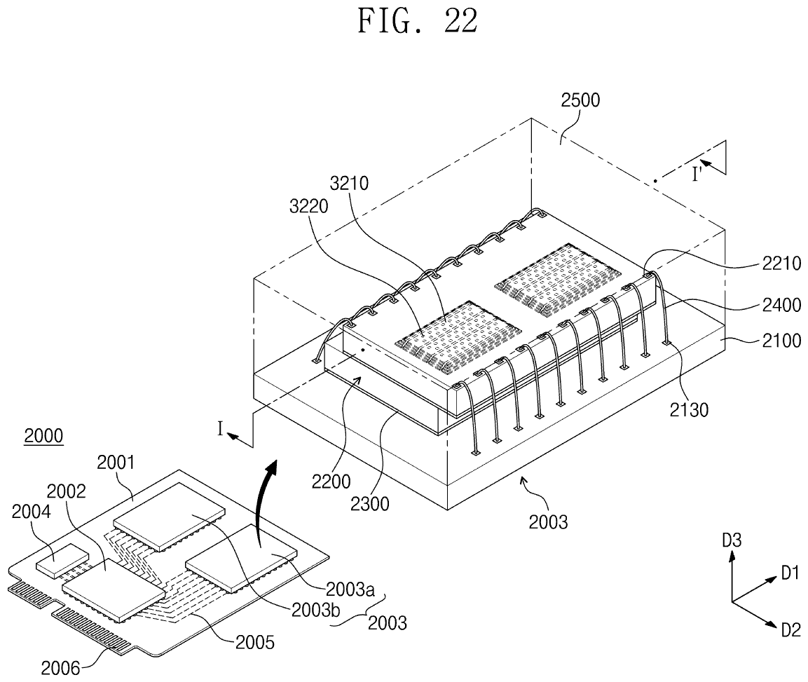

FIG. 22 illustrates a simplified diagram showing an electronic system including a semiconductor memory device according to some embodiments of the present disclosure.

Referring to FIG. 22, an electronic system 2000 according to some embodiments of the present disclosure may include a main board 2001, and may also include a controller 2002, at least one semiconductor package 2003, and a dynamic random access memory (DRAM) 2004 that are mounted on the main board 2001. The semiconductor package 2003 and the DRAM 2004 may be connected to the controller 2002 through wiring patterns 2005 formed on the main board 2001.

The main board 2001 may include a connector 2006 including a plurality of pins that are coupled to an external host. The number and arrangement of the plurality of pins in the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be a printed circuit board including upper pads 2130. Each of the semiconductor chips 2200 may include one or more input/output pads 2210. The input/output pad 2210 may correspond to the input/output pad 1101 of FIG. 21. Each of the semiconductor chips 2200 may include stack structures 3210 and vertical structures 3220. Each of the semiconductor chips 2200 may include the aforementioned semiconductor memory device according to some embodiments of the present disclosure.

In some embodiments, the connection structure 2400 may be a bonding wire that electrically connects the input/output pad 2210 to the upper pad 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. In some embodiments, in each of the first and second semiconductor packages 2003a and 2003b, the semiconductor chips 2200 may be electrically connected to each other through connection structures such as through silicon vias (TSV) instead of the connection structures 2400 shaped like bonding wires.

In some embodiments, the controller 2002 and the semiconductor chips 2200 may be included in a single package. For example, the controller 2002 and the semiconductor chips 2200 may be mounted on an interposer substrate other than the main board 2001, and may be connected to each other through wiring lines formed on the interposer substrate.

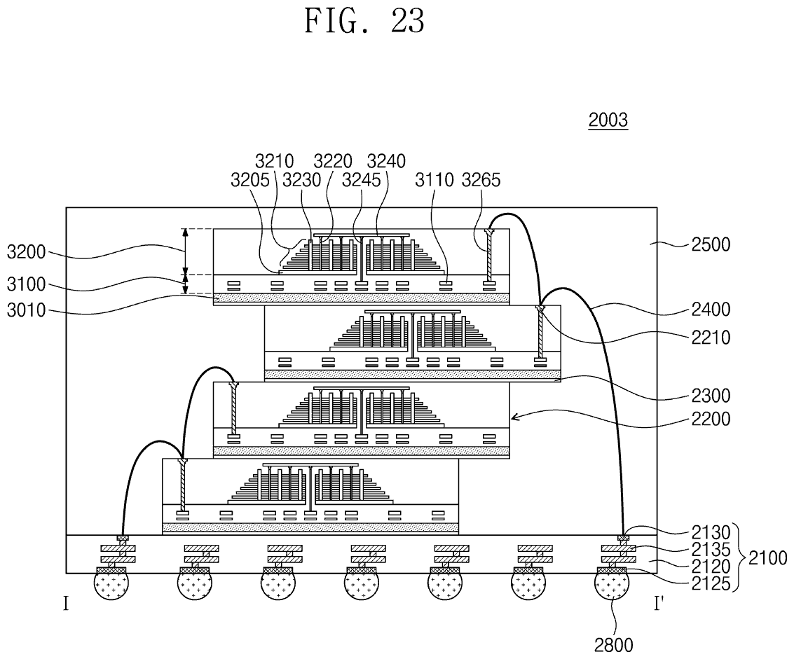

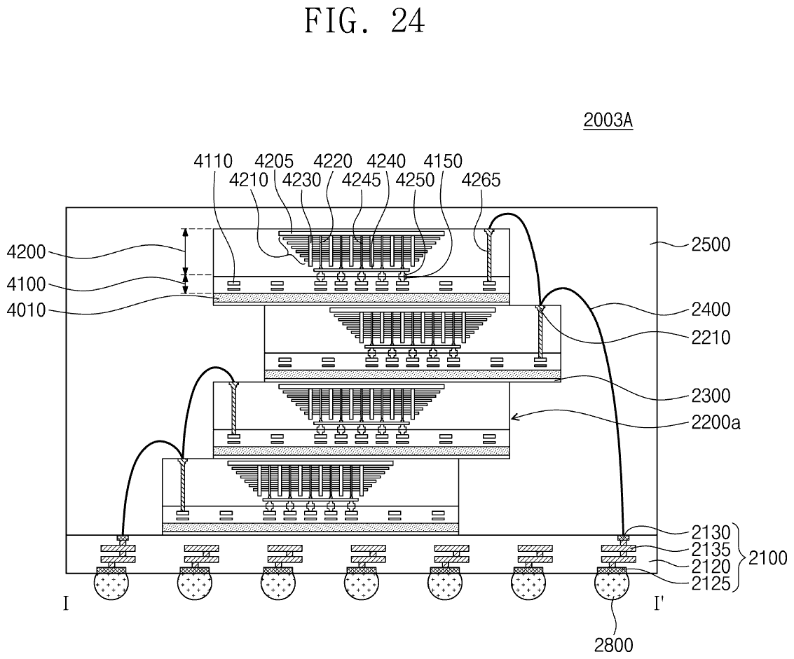

FIGS. 23 and 24 illustrate simplified cross-sectional views showing a semiconductor package according to some embodiments of the present disclosure. FIGS. 23 and 24 each depicts an example of the semiconductor package illustrated in FIG. 22, conceptually showing a section taken along line I-I′ of the semiconductor package illustrated in FIG. 22.

Referring to FIG. 23, a printed circuit board may be used as the package substrate 2100 of the semiconductor package 2003. The package substrate 2100 may include a package substrate body 2120, upper pads (see 2130 of FIG. 22) disposed on a top surface of the package substrate body 2120, lower pads 2125 disposed or exposed on a bottom surface of the package substrate body 2120, and internal lines 2135 by which the upper pads 2130 and the lower pads 2125 are electrically connected to each other in the package substrate body 2120. The upper pads 2130 may be electrically connected to the connection structures 2400. The lower pads 2125 may be connected through conductive connectors 2800 to the wiring patterns 2005 of the main board 2001 in the electronic system 2000, as shown in FIG. 22.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a source structure 3205, a stack structure 3210 on the source structure 3205, vertical structures 3220 and separation structures 3230 that penetrate or extend into the stack structure 3210, bit lines 3240 electrically connected to the vertical structures 3220, and cell contact plugs electrically connected to word lines WL of the stack structure 3210. Each of the first structure 3100, the second structure 3200, and the semiconductor chips 2200 may further include structures which are discussed above.

Each of the semiconductor chips 2200 may include one or more through wiring lines 3245 that extend into the second structure 3200 and are electrically connected to the peripheral wiring lines 3110 of the first structure 3100. The through wiring line 3245 may be disposed outside the stack structure 3210 and may further be disposed to penetrate or extend into the stack structure 3210. Each of the semiconductor chips 2200 may further include one or more input/output pads (see 2210 of FIG. 22) electrically connected to the peripheral wiring lines 3110 of the first structure 3100.

Each of the semiconductor chips 2200 may further include an input/output interconnection wiring 3265 electrically connected to the peripheral wirings 3110 of the first structure 3100 and extended in the second structure 3200, and an input/output pad 2210 electrically connected to the input/output interconnection wiring 3265. For example, the input/output interconnection wiring 3265 may extend in a vertical direction from the first structure 3100 through the second structure 3200 to contact the input/output pad 2210.

Referring to FIG. 24, a semiconductor package 2003A may be configured such that each of semiconductor chips 2200a may include a semiconductor substrate 4010, a first structure 4100 on the semiconductor substrate 4010, and a second structure 4200 disposed on and wafer-bonded to the first structure 4100.

The first structure 4100 may include a peripheral circuit region including peripheral wiring lines 4110 and first bonding structures 4150. The second structure 4200 may include a source structure 4205, a stack structure 4210 between the source structure 4205 and the first structure 4100, vertical structures 4220 and separation structures 4230 that penetrate or extend into the stack structure 4210, and second bonding structures 4250 electrically connected to the vertical structures 4220 and word lines WL of the stack structure 4210. For example, the second bonding structures 4250 may be correspondingly electrically connected to the vertical structures 4220 and the word lines WL through bit lines 4240 electrically connected to the vertical structures 4220 and cell contact plugs electrically connected to the word lines WL. The first bonding structures 4150 of the first structure 4100 and the second bonding structures 4250 of the second structure 4200 may be bonded to each other while being in contact with each other. The first and second bonding structures 4150 and 4250 may have their bonding portions formed of, for example, copper (Cu).

Each of the first structure 4100, the second structure 4200, and the semiconductor chip 2200a may further include structures discussed above. Each of the semiconductor chips 2200a may further include one or more input/output pads (see 2210 of FIG. 22) electrically connected to the peripheral wiring lines 4110 of the first structure 4100.

Each of the semiconductor chips 2200 may further include an input/output pad 2210 and an input/output interconnection wiring 4265 under the input/output pad 2210. The input/output interconnection wiring 4265 may be electrically connected to the peripheral wirings 4110 of the first structure 4100.

The semiconductor chips 2200 of FIG. 23 may be electrically connected to each other through the connection structures 2400 shaped like bonding wires, and this may also be applicable to the semiconductor chips 2200a of FIG. 24. In some embodiments, semiconductor chips, such as the semiconductor chips 2200 of FIG. 23 or the semiconductor chips 2200a of FIG. 24, in a single semiconductor package may be electrically connected to each other through one or more connection structures including through silicon vias (TSV).

According to some embodiments of the present disclosure, a semiconductor device may be fabricated by separately forming first and second array structures on different substrates, and then bonding the first and second cell array structures. First word lines of the first cell array structure may be connected to second word lines of the second cell array structure, first bit lines may be separated or spaced apart from second bit lines, and a first common source line may be separated or spaced apart from a second common source line.

Therefore, an erase operation may be independently performed on the first cell array structure and the second cell array structure, and even when there is a difference in erase operation characteristics between memory cells of the first cell array structure and memory cells of the second cell array structure, it may be possible to prevent or inhibit an increase in erase threshold voltage distribution after the erase operation.

Although the present disclosure has been described in connection with some embodiments of the present disclosure illustrated in the accompanying drawings, it will be understood to those skilled in the art that various changes and modifications may be made without departing from the technical spirit and essential feature of the present disclosure. It will be apparent to those skilled in the art that various substitution, modifications, and changes may be thereto without departing from the scope and spirit of the present disclosure.

What is claimed is:

1. A semiconductor memory device, comprising:
a first cell array structure that comprises a plurality of first cell strings and a plurality of first bonding pads electrically connected to the plurality of first cell strings, wherein the first cell strings are electrically connected to a first bit line of the first cell array structure and a first common source line of the first cell array structure, and wherein each of the plurality of first cell strings comprises a plurality of first memory cells that are electrically connected to a plurality of first word lines of the first cell array structure; and
a second cell array structure that comprises a plurality of second cell strings and a plurality of second bonding pads electrically connected to the plurality of second cell strings, wherein the second cell strings are electrically connected to a second bit line of the second cell array structure and a second common source line of the second cell array structure, and wherein each of the plurality of second cell strings comprises a plurality of second memory cells that are electrically connected to a plurality of second word lines of the second cell array structure,
wherein the plurality of first bonding pads are directly bonded to the plurality of second bonding pads,
wherein the plurality of first word lines are respectively electrically connected to the plurality of second word lines,
wherein the first bit line is electrically separated from the second bit line, and
wherein the first common source line is electrically separated from the second common source line.

2. The semiconductor memory device of claim 1, further comprising:
a peripheral circuit structure that comprises a row decoder, a page buffer, and a common source line (CSL) voltage controller that are on a substrate;
a plurality of first connection lines that electrically connect respective ones of the plurality of first word lines and respective ones of the plurality of second word lines to the row decoder;
a first bit-line connection line that electrically connects the first bit line to the page buffer;
a second bit-line connection line that electrically connects the second bit line to the page buffer;
a first source connection line that electrically connects the first common source line to the CSL voltage controller; and
a second source connection line that electrically connects the second common source line to the CSL voltage controller.

3. The semiconductor memory device of claim 2, wherein:
the peripheral circuit structure further comprises a plurality of third bonding pads electrically connected to the row decoder, the page buffer, and the CSL voltage controller, and
the plurality of third bonding pads are respectively directly bonded to the plurality of first bonding pads.

4. The semiconductor memory device of claim 1, wherein the first common source line and the second common source line are between the first bit line and the second bit line.

5. The semiconductor memory device of claim 1, wherein the first bit line and the second bit line are between the first common source line and the second common source line.

6. The semiconductor memory device of claim 1, wherein:
each of the plurality of first cell strings comprises a first vertical structure that extends in a first direction and into the plurality of first word lines,
the first vertical structure comprises:
a first bit-line conductive pad electrically connected to the first bit line, and
a first source conductive pad electrically connected to the first common source line,
each of the plurality of second cell strings comprises a second vertical structure that extends in the first direction and into the plurality of second word lines, and
the second vertical structure comprises:
a second bit-line conductive pad electrically connected to the second bit line, and
a second source conductive pad electrically connected to the second common source line.

7. The semiconductor memory device of claim 6, wherein:
a width of a bottom surface of the first vertical structure in a second direction that is perpendicular to the first direction is less than a width of a top surface of the first vertical structure in the second direction,
the bottom surface of the first vertical structure is adjacent to the first bit line, and the top surface of the first vertical structure is adjacent to the first common source line,
a width of a top surface of the second vertical structure in the second direction is less than a width of a bottom surface of the second vertical structure in the second direction, and
the bottom surface of the second vertical structure is adjacent to the second bit line, and the top surface of the second vertical structure is adjacent to the second common source line.

8. The semiconductor memory device of claim 1, wherein:
the first cell array structure further comprises a plurality of first cell contact plugs that extend into the first word lines and respectively contact sidewalls of the first word lines, and
the second cell array structure further comprises a plurality of second cell contact plugs that extend into the second word lines and contact sidewalls of respective ones of the second word lines.

9. The semiconductor memory device of claim 1, wherein:
the first cell array structure further comprises:
a plurality of first through plugs that extend into the first word lines; and
a plurality of first sidewall dielectric patterns that at least partially surround sidewalls of the first through plugs in plan view,
wherein the first through plugs are respectively electrically connected to the first word lines,
wherein the second cell array structure further comprises:
a plurality of second through plugs that extend into the second word lines; and
a plurality of second sidewall dielectric patterns that at least partially surround sidewalls of the second through plugs in the plan view,
wherein the second through plugs are respectively electrically connected to the second word lines.

10. The semiconductor memory device of claim 1, further comprising a third cell array structure that comprises a plurality of third cell strings and a plurality of third bonding pads respectively electrically connected to the third cell strings, wherein the plurality of third cell strings are electrically connected between a third bit line and a third common source line,
wherein each of the plurality of third cell strings comprises a plurality of third memory cells that are respectively electrically connected to a plurality of third word lines,
wherein the third bonding pads are respectively directly bonded to the second bonding pads, and
wherein the third word lines are respectively electrically connected to the second word lines.

11. A semiconductor memory device, comprising:
a peripheral circuit structure that comprises a plurality of peripheral circuits on a substrate and a plurality of first bonding pads electrically connected to the peripheral circuits;
a first cell array structure that comprises a plurality of second bonding pads that are on a first surface of the first cell array structure and are respectively electrically connected to the first bonding pads, wherein the first cell array structure comprises a plurality of third bonding pads that are on a second surface of the first cell array structure that is opposite to the first surface of the first cell array structure, wherein the first cell array structure comprises a first stack and a plurality of first vertical structures that extend into the first stack, the first stack comprising a first bit line, a first common source line, and a plurality of first word lines between the first bit line and the first common source line;
a second cell array structure that comprises a plurality of fourth bonding pads respectively electrically connected to the third bonding pads, wherein the second cell array structure comprises a second stack and a plurality of second vertical structures that extend into the second stack, the second stack comprising a second bit line, a second common source line, and a plurality of second word lines between the second bit line and the second common source line;
a plurality of first connection lines that electrically connect respective ones of the first word lines to respective ones of the second word lines;
a first bit-line connection line and a second bit-line connection line that are respectively electrically connected to the first bit line and the second bit line; and
a first source connection line and a second source connection line that are respectively electrically connected to the first common source line and the second common source line.

12. The semiconductor memory device of claim 11, wherein the plurality of peripheral circuits comprise:
a row decoder electrically connected to the first connection lines;
a page buffer electrically connected to the first and second bit-line connection lines; and
a common source line (CSL) voltage controller electrically connected to the first and second source connection lines.

13. The semiconductor memory device of claim 11, wherein the first common source line and the second common source line are between the first bit line and the second bit line.

14. The semiconductor memory device of claim 11, wherein the first bit line and the second bit line are between the first common source line and the second common source line.

15. The semiconductor memory device of claim 11,
wherein each of the first vertical structures comprises:
a first bit-line conductive pad electrically connected to the first bit line; and
a first source conductive pad electrically connected to the first common source line, and
wherein each of the second vertical structures comprises:
a second bit-line conductive pad electrically connected to the second bit line; and
a second source conductive pad electrically connected to the second common source line.

16. The semiconductor memory device of claim 11, wherein:
each of the plurality of first vertical structures comprises a bottom surface adjacent to the first bit line and a top surface adjacent to the first common source line, and
a width of the bottom surface in a first direction that is parallel to an upper surface of the substrate is less than a width of the top surface in the first direction.

17. The semiconductor memory device of claim 11, wherein:
each of the second vertical structures comprises a top surface adjacent to the second bit line and a bottom surface adjacent to the second common source line, and
a width of the bottom surface in a first direction that is parallel to an upper surface of the substrate is greater than a width of the top surface in the first direction.

18. The semiconductor memory device of claim 11, further comprising a third cell array structure that comprises a third stack and a plurality of third vertical structures that extend into the third stack, the third stack comprising a third bit line, a third common source line, and a plurality of third word lines between the third bit line and the third common source line,
wherein the plurality of third word lines are respectively electrically connected to the plurality of first connection lines.

19. The semiconductor memory device of claim 11, further comprising:
a plurality of first cell contact plugs that extend into the first stack and contact sidewalls of respective ones of the plurality of first word lines; and
a plurality of second cell contact plugs that extend into the second stack and contact sidewalls of respective ones of the plurality of second word lines,
wherein the plurality of second cell contact plugs at least partially overlap the plurality of first cell contact plugs in a first direction that is perpendicular to an upper surface of the substrate.

20. An electronic system, comprising:
a semiconductor memory device that comprises a peripheral circuit structure and a memory block on the peripheral circuit structure; and
a controller electrically connected to and configured to control the semiconductor memory device,
wherein the memory block comprises:
a first cell array structure that comprises a plurality of first cell strings and a plurality of first bonding pads electrically connected to the plurality of first cell strings, wherein the plurality of first cell strings are electrically connected between a first bit line of the first cell array structure and a first common source line of the first cell array structure, and wherein each of the plurality of first cell strings comprises a plurality of first memory cells that are electrically connected to a plurality of first word lines of the first cell array structure; and
a second cell array structure that comprises a plurality of second cell strings and a plurality of second bonding pads electrically connected to the plurality of second cell strings, wherein the plurality of second cell strings are electrically connected between a second bit line of the second cell array structure and a second common source line of the second cell array structure, and wherein each of the plurality of second cell strings comprises a plurality of second memory cells that are electrically connected to a plurality of second word lines of the second cell array structure,
wherein the plurality of first bonding pads are directly bonded to the second bonding pads,
wherein the plurality of first word lines are electrically connected to the plurality of second word lines,
wherein the first bit line is electrically separated from the second bit line, and
wherein the first common source line is spaced apart from the second common source line.
